(19) United States
(12) Patent Application Publication
(10) Pub. No.: US 2024/0357831 A1
(43) Pub. Date: Oct. 24, 2024

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Seryeun Yang, Suwon-si (KR); Jeon Il Lee, Suwon-si (KR); Hyeran Lee, Suwon-si (KR); Hyun-Mook Choi, Suwon-si (KR)

(73) Assignee: SAMSUNG ELECTRONICS CO., LTD., Suwon-si (KR)

(21) Appl. No.: 18/532,504

(22) Filed: Dec. 7, 2023

(30) Foreign Application Priority Data
Apr. 24, 2023 (KR) 10-2023-0053133

(51) Int. Cl. H10B 53/20; H01L 21/28; H01L 29/51; H01L 29/78; H10B 51/10; H10B 51/20; H10B 53/10

(52) U.S. Cl. CPC H10B 53/20; H01L 29/40111; H01L 29/516; H01L 29/78391; H10B 51/10; H10B 51/20; H10B 53/10

(57) ABSTRACT

A semiconductor device may include a substrate; semiconductor patterns that are stacked on the substrate, extend in a first direction parallel to a top surface of the substrate, and are spaced apart from each other; a gate electrode including horizontal portions, that extend in a second direction crossing the first direction, and a vertical portion, that is in contact with the horizontal portions and extends in a third direction perpendicular to the top surface of the substrate; a gate dielectric layer between the semiconductor patterns and the gate electrode; and a ferroelectric layer between the gate dielectric layer and the gate electrode. Each of the semiconductor patterns may include impurity regions and a channel region between the impurity regions, the vertical portion may be on a first side surface of the channel region, and the horizontal portions may be on a top and bottom surface of the channel region.

### CROSS-REFERENCE TO RELATED APPLICATIONS

This U.S. non-provisional patent application claims priority under 35 U.S.C. § 119 to Korean Patent Application No. 10-2023-0053133, filed on Apr. 24, 2023, in the Korean Intellectual Property Office, the entire contents of which are hereby incorporated by reference.

### BACKGROUND

### 1. Technical Field

Embodiments of the present disclosure relate to a semiconductor device and a method of fabricating the same, and in particular, to a three-dimensional semiconductor memory device using a ferroelectric material and a method of fabricating the same.

### 2. Description of Related Art

Semiconductor memory devices are generally classified into volatile memory devices and nonvolatile memory devices. The volatile memory devices lose their stored data when their power supplies are interrupted, and for example, include a dynamic random access memory (DRAM) device and a static random access memory (SRAM) device. The nonvolatile memory devices maintain their stored data even when their power supplies are interrupted and, for example, include a programmable read only memory (PROM), an erasable PROM (EPROM), an electrically EPROM (EEPROM), and a flash memory device. In addition, to meet an increasing demand for a semiconductor memory device with high performance and low power consumption, next-generation nonvolatile semiconductor memory devices, such as magnetic random access memory (MRAM), phase-change random access memory (PRAM), and ferroelectric random access memory (FeRAM) devices, are being developed.

### SUMMARY

An embodiment of the present disclosure provide a semiconductor device using a ferroelectric material and a method of fabricating the same.

According to embodiments of the present disclosure, a semiconductor device, is provided and includes: a substrate; semiconductor patterns that are stacked on the substrate, extend in a first direction parallel to a top surface of the substrate, and are spaced apart from each other; a gate electrode including horizontal portions, that extend in a second direction crossing the first direction, and a vertical portion, that is in contact with the horizontal portions and extends in a third direction perpendicular to the top surface of the substrate; a gate dielectric layer between the semiconductor patterns and the gate electrode; and a ferroelectric layer between the gate dielectric layer and the gate electrode, wherein each of the semiconductor patterns includes impurity regions and a channel region between the impurity regions, the vertical portion is on a first side surface of the channel region, and the horizontal portions are on a top surface and a bottom surface of the channel region.

According to embodiments of the present disclosure, a semiconductor device, is provided and includes: a substrate; semiconductor patterns that are on the substrate and spaced apart from each other in a vertical direction, the semiconductor patterns including a first side surface and a second side surface that are opposite to each other; an outer gate electrode including a vertical portion, that is on the first side surface, and a horizontal portion, that protrudes from the vertical portion; an inner gate electrode on the second side surface of the semiconductor patterns; a first ferroelectric layer between the outer gate electrode and the semiconductor patterns; and a second ferroelectric layer between the inner gate electrode and the semiconductor patterns, wherein the horizontal portion extends between two of the semiconductor patterns that are adjacent to each other in the vertical direction.

According to embodiments of the present disclosure, a semiconductor device, is provided and includes: a substrate; an insulating layer on the substrate; first semiconductor patterns that are on the insulating layer, extend in a first direction parallel to a top surface of the substrate, and are spaced apart from each other in a vertical direction; second semiconductor patterns that are on the insulating layer, extend in the first direction, and are spaced apart from each other in the vertical direction; an insulating pattern between the first semiconductor patterns and the second semiconductor patterns; a bit line extending in a second direction crossing the first direction and connected to at least one of the first semiconductor patterns and at least one of the second semiconductor patterns; a first gate structure on bottom surfaces, top surfaces, and outer side surfaces of the first semiconductor patterns; and a second gate structure on bottom surfaces, top surfaces, and outer side surfaces of the second semiconductor patterns, wherein the first semiconductor patterns are spaced apart from the second semiconductor patterns in the second direction, and wherein the first gate structure and the second gate structure are symmetrical to each other in the second direction.

According to embodiments of the present disclosure, a method of fabricating a semiconductor device is provided and includes: forming a stack structure including interlayer insulating layers and semiconductor layers, which are alternatingly stacked on a substrate; forming, by patterning the stack structure, semiconductor patterns that extend in a first direction parallel to a top surface of the substrate and are spaced apart from each other in a vertical direction; forming, by partially removing the interlayer insulating layers, an internal space between the semiconductor patterns that are adjacent to each other in the vertical direction; and forming a gate structure in the internal space and on side surfaces of the semiconductor patterns, wherein the gate structure includes a gate electrode, a gate insulating layer, and a ferroelectric layer, and wherein the gate structure is on top surfaces, bottom surfaces, and the side surfaces of the semiconductor patterns.

### BRIEF DESCRIPTION OF THE DRAWINGS

FIG. 1 is a block diagram illustrating a semiconductor device according to an embodiment of the present disclosure.

FIG. 2 is a perspective view that illustrates a semiconductor device according to an embodiment of the present disclosure.

FIG. 3 is a perspective view that illustrates a semiconductor device according to an embodiment of the present disclosure.

FIG. 4 is a perspective view that illustrates a semiconductor device according to an embodiment of the present disclosure.

FIG. 5 is a circuit diagram illustrating a semiconductor device according to an embodiment of the present disclosure.

FIG. 6 is a plan view illustrating a semiconductor device according to an embodiment of the present disclosure.

FIG. 7A is a sectional view, which is taken along a line A-A′ of FIG. 6, to illustrate a semiconductor device according to an embodiment of the present disclosure.

FIG. 7B is a sectional view, which is taken along a line B-B′ of FIG. 6, to illustrate a semiconductor device according to an embodiment of the present disclosure.

FIG. 8 is an enlarged sectional view illustrating a portion ‘P’ of FIG. 7A.

FIG. 9A is a sectional view, which is taken along the line A-A′ of FIG. 6, to illustrate a semiconductor device according to an embodiment of the present disclosure.

FIG. 9B is a sectional view, which is taken along the line B-B′ of FIG. 6, to illustrate a semiconductor device according to an embodiment of the present disclosure.

FIG. 10A is a sectional view, which is taken along line A-A′ of FIG. 6, to illustrate a semiconductor device according to an embodiment of the present disclosure.

FIG. 10B is a sectional view, which is taken along line B-B′ of FIG. 6, to illustrate a semiconductor device according to an embodiment of the present disclosure.

FIG. 11 is a plan view illustrating a semiconductor device according to an embodiment of the present disclosure.

FIG. 12 is a sectional view, which is taken along a line C-C′ of FIG. 11, to illustrate a semiconductor device according to an embodiment of the present disclosure.

FIG. 13 is a circuit diagram illustrating a semiconductor device according to an embodiment of the present disclosure.

FIG. 14 is a plan view illustrating a semiconductor device according to an embodiment of the present disclosure.

FIG. 15 is a sectional view, which is taken along a line D-D′ of FIG. 14 to illustrate a semiconductor device according to an embodiment of the present disclosure.

FIG. 16 is a circuit diagram illustrating a semiconductor device according to an embodiment of the present disclosure.

FIG. 17 is a plan view illustrating a semiconductor device according to an embodiment of the present disclosure.

FIG. 18 is a sectional view, which is taken along a line E-E′ of FIG. 17 to illustrate a semiconductor device according to an embodiment of the present disclosure.

FIGS. 19A to 24B are diagrams illustrating a method of fabricating a semiconductor device, according to an embodiment of the present disclosure.

FIGS. 25A to 26B are diagrams illustrating a method of fabricating a semiconductor device, according to an embodiment of the present disclosure.

### DETAILED DESCRIPTION

Example embodiments of the present disclosure will now be described more fully with reference to the accompanying drawings, in which example embodiments are shown. Like reference numerals in the drawings denote like elements, and thus repeated description thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

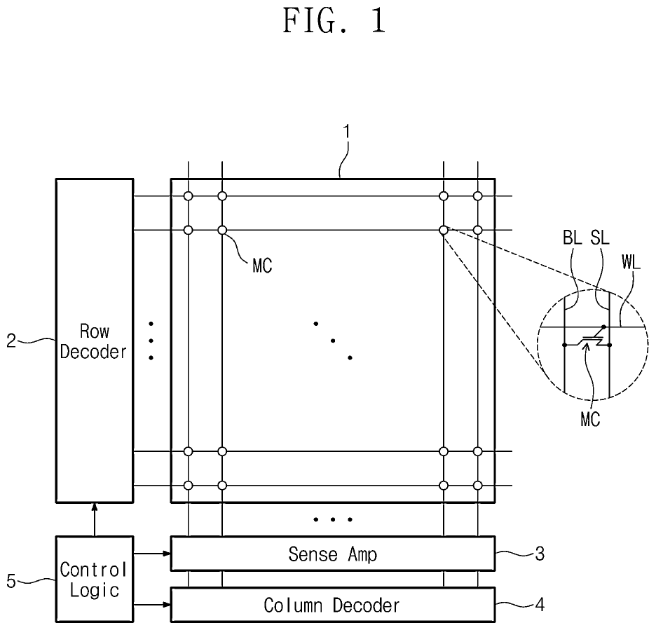

FIG. 1 is a block diagram illustrating a semiconductor device according to an embodiment of the present disclosure.

Referring to FIG. 1, a semiconductor device may include a memory cell array 1, a row decoder 2, a sense amplifier 3, a column decoder 4, and a control logic 5.

The memory cell array 1 may include word lines WL, bit lines BL, source lines SL, and memory cells MC. The memory cells MC may be three-dimensionally arranged, and each memory cell MC may be connected to one of the word lines WL, one of the bit lines BL, and one of the source lines SL. In an embodiment, each of the memory cells MC may be composed of one transistor including a memory layer (or a data storing layer).

The row decoder 2 may be configured to decode address information, which is input from the outside, and to select one of the word lines WL of the memory cell array 1, based on the decoded address information. The address information decoded by the row decoder 2 may be provided to a row driver, and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may provide a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data-writing or data-reading operations on the memory cell array 1.

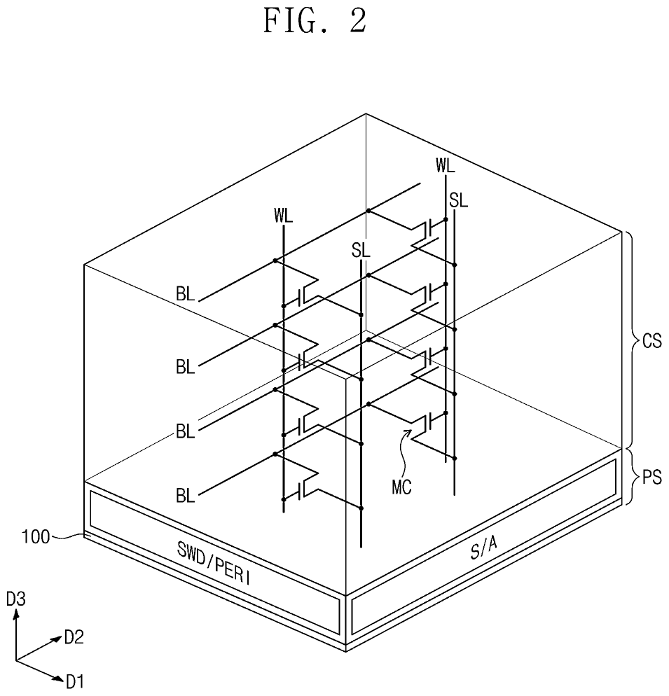

FIGS. 2 to 4 are perspective views, each of which illustrates a semiconductor device according to an embodiment of the present disclosure.

Referring to FIG. 2, a semiconductor device may include a peripheral circuit structure PS on a substrate 100 and a cell array structure CS on the peripheral circuit structure PS.

The peripheral circuit structure PS may include core and peripheral circuits, which are formed on the substrate 100. The core and peripheral circuits may include the row decoder 2, the column decoder 4, the sense amplifier 3, and the control logic 5 of FIG. 1. The peripheral circuit structure PS may be provided between the substrate 100 and the cell array structure CS, in a third direction D3 perpendicular to a top surface of the substrate 100.

The cell array structure CS may include the bit lines BL, the source lines SL, and the word lines WL, and the memory cells MC therebetween. The memory cells MC may be arranged in a second direction D2, which is parallel to the top surface of the substrate 100, and in the third direction D3, which is perpendicular to the top surface of the substrate 100.

Each of the memory cells MC may be connected to one of the word lines WL, one of the bit lines BL, and one of the source lines SL. Each of the memory cells MC may include a ferroelectric field effect transistor (FeFET). For example, each of the memory cells MC may include a ferroelectric layer, which is used as the memory layer. In each memory cell MC, the ferroelectric layer may have a non-centrosymmetric charge distribution and thereby may have a spontaneous dipole (i.e., spontaneous polarization). Even when there is no external electric field, the ferroelectric layer may have a remnant polarization caused by the dipole. In addition, a polarization direction of the ferroelectric layer may be switched by an external electric field.

For example, the ferroelectric layer may have a positive or negative polarization state, and the polarization state may be changed by an electric field exerted on the ferroelectric layer during a program operation. Even when power is interrupted, the polarization state of the ferroelectric layer may be maintained, and thus, the semiconductor memory device may be operated as a nonvolatile memory device.

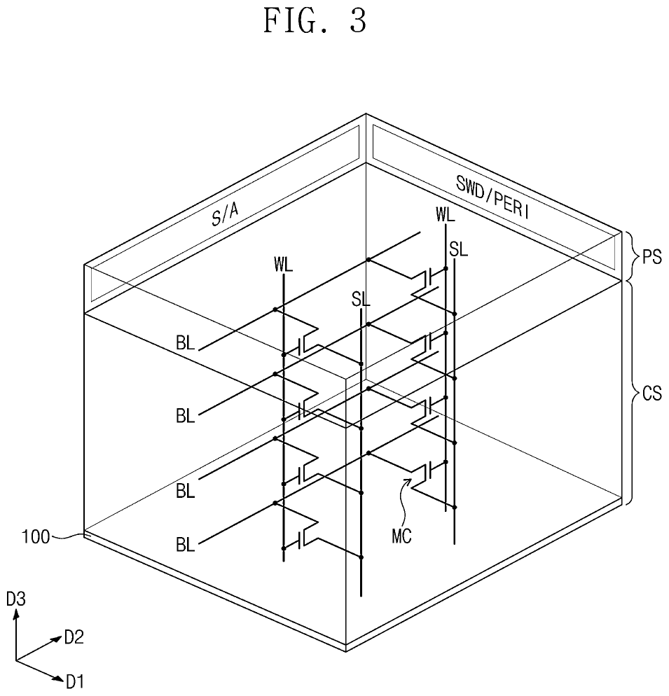

Referring to FIG. 3, the semiconductor device may include the cell array structure CS on the substrate 100 and the peripheral circuit structure PS on the cell array structure CS. In other words, the cell array structure CS may be disposed between the substrate 100 and the peripheral circuit structure PS, in the third direction D3.

As described above, the cell array structure CS may include the bit lines BL, the source lines SL, the word lines WL, and the memory cells MC therebetween. As described above, each of the memory cells MC may be composed of one transistor, which includes a memory layer, and in an embodiment, the ferroelectric layer may be used as the memory layer.

The peripheral circuit structure PS may include the core and peripheral circuits, as described above.

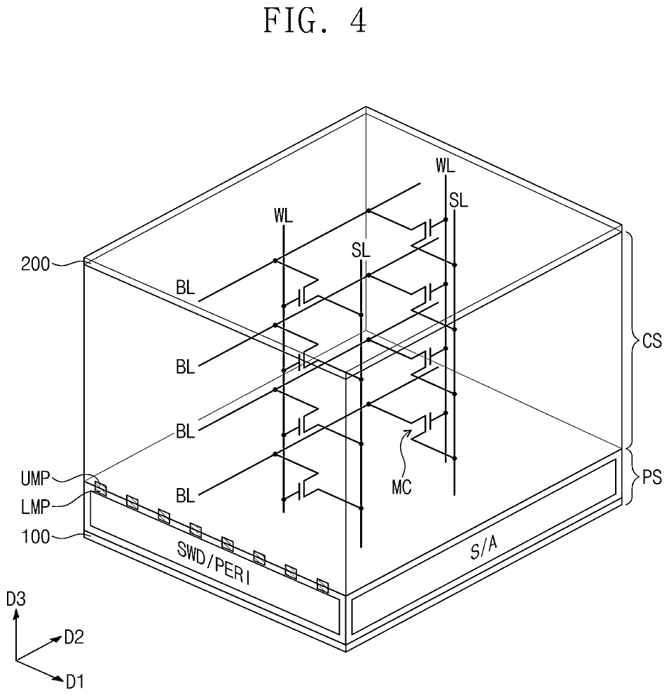

Referring to FIG. 4, the semiconductor device may have a chip-to-chip (C2C) structure. For example, the C2C structure may be formed by fabricating a lower chip, which includes the peripheral circuit structure PS, on a substrate 100 (a first substrate), and fabricating an upper chip, which includes the cell array structure CS, on a second substrate. Thereafter, the upper chip and the lower chip may be connected to each other by a bonding method. Here, the bonding method may refer to a method of electrically connecting bonding metal pads, which are formed in the uppermost metal layer of the upper chip, to bonding metal pads, which are formed in the uppermost metal layer of the lower chip. For example, in the case where the bonding metal pad is formed of copper (Cu), the bonding method may be performed in a Cu-to-Cu bonding manner, but in an embodiment, the bonding metal pad may be formed of or include aluminum (Al) or tungsten (W).

In detail, the peripheral circuit structure PS may be provided on the substrate 100, and lower metal pads LMP may be provided in the uppermost layer of the peripheral circuit structure PS. The lower metal pads LMP may be electrically connected to the core and peripheral circuits (e.g., the row decoder 2, the sense amplifier 3, the column decoder 4, and the control logic 5) of FIG. 1.

The cell array structure CS may be provided on the second substrate 200, and upper metal pads UMP may be provided at the uppermost level of the cell array structure CS. The upper metal pads UMP may be connected to the bit lines BL, the source lines SL, and the word lines WL. That is, the upper metal pads UMP may be electrically connected to the memory cells MC. The upper metal pads UMP of the cell array structure CS may be in direct contact with and bonded to the lower metal pads LMP of the peripheral circuit structure PS.

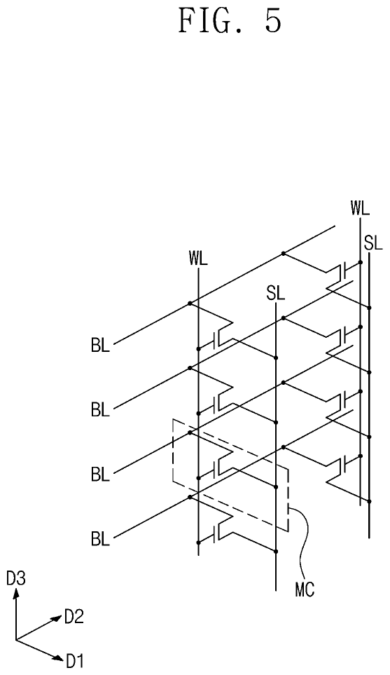

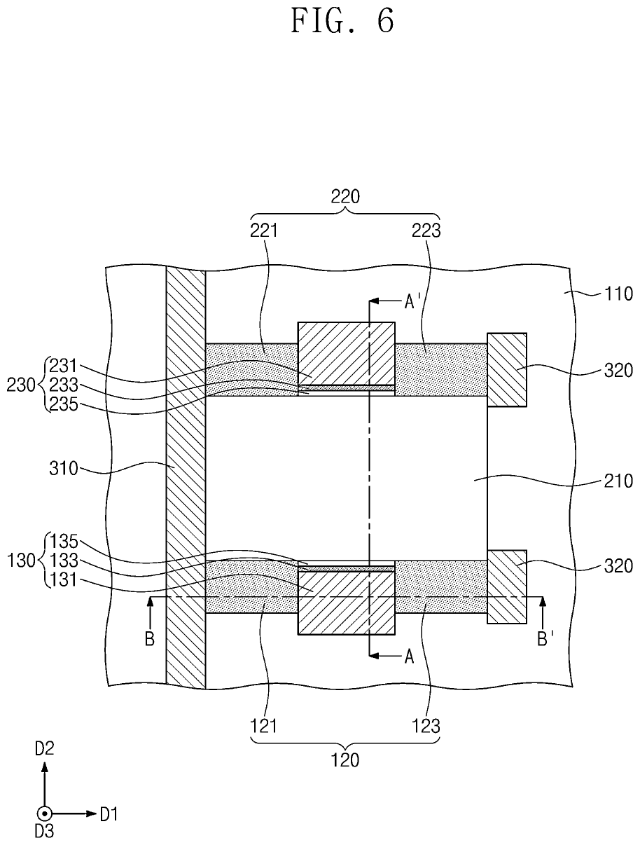

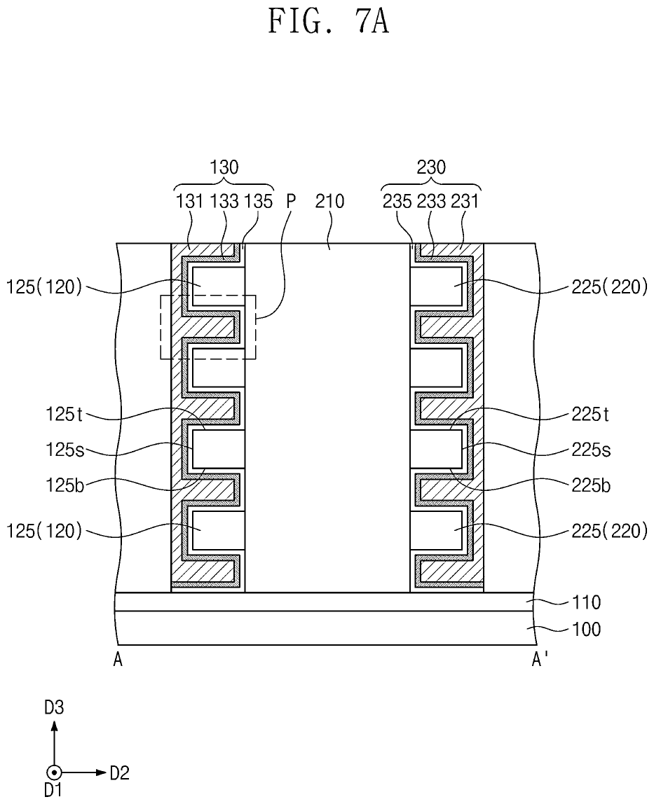

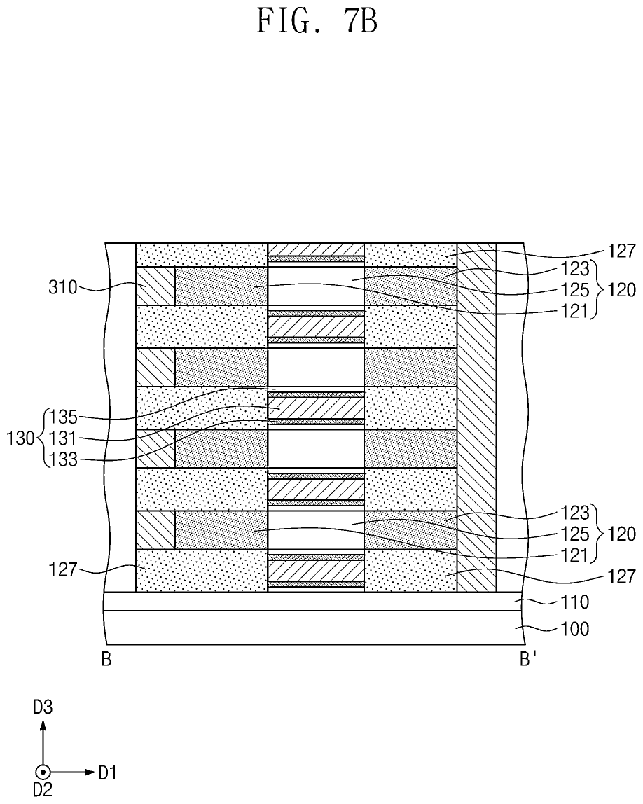

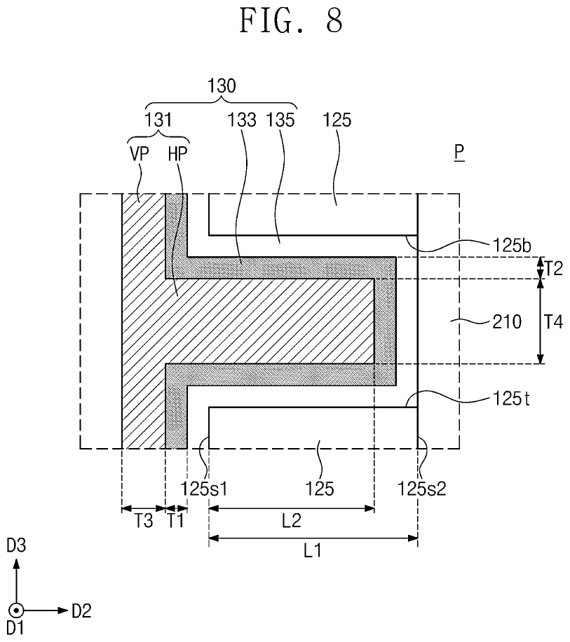

FIG. 5 is a circuit diagram illustrating a semiconductor device according to an embodiment of the present disclosure. FIG. 6 is a plan view illustrating a semiconductor device according to an embodiment of the present disclosure. FIGS. 7A and 7B are sectional views, which are respectively taken along lines A-A′ and B-B′ of FIG. 6 to illustrate a semiconductor device according to an embodiment of the present disclosure. FIG. 8 is an enlarged sectional view illustrating a portion ‘P’ of FIG. 7A.

Referring to FIG. 5, a semiconductor device according to an embodiment of the present disclosure may include the word lines WL, the bit lines BL, the source lines SL, and the memory cells MC. The memory cells MC may be unit memory cells of a ferroelectric random access memory (FeRAM) device.

The word lines WL may extend in the third direction D3 and parallel to each other. The word lines WL may be spaced apart from each other in the second direction D2. Each of the word lines WL may be connected to the memory cells MC arranged in the third direction D3. For example, each of the word lines WL may be electrically connected to gate terminals of the memory cells MC, which are arranged in the third direction D3 or stacked in a vertical direction.

The bit lines BL may extend in the second direction D2 and parallel to each other. The bit lines BL may be spaced apart from each other in the third direction D3. Each of the bit lines BL may be connected to the memory cells MC arranged in the second direction D2. The bit lines BL may be electrically connected to drain terminals of the memory cells MC.

The source lines SL may extend in the third direction D3 and parallel to each other. The source lines SL may be spaced apart from each other in the second direction D2. Each of the source lines SL may be connected to the memory cells MC arranged in the third direction D3. The source lines SL may be electrically connected to source terminals of the memory cells MC.

The memory cells MC, which are connected to one of the bit lines BL, may be connected to different ones of the source lines SL. For example, the memory cells MC, which are arranged in the second direction D2 at the same height or level, may be connected in common to one of the bit lines BL. The memory cells MC, which are connected to one of the source lines SL, may be connected to different ones of the bit lines BL. In other words, the memory cells MC, which are the third direction D3 arranged, may be connected in common to one of the source lines SL.

Referring to FIGS. 6, 7A, and 7B, a semiconductor device may include an insulating layer 110, first semiconductor patterns 120, second semiconductor patterns 220, a first gate structure 130, and a second gate structure 230, which are disposed on the substrate 100. In the present specification, a first direction D1 may be a direction that is parallel to the top surface of the substrate 100. The second direction D2 may be a direction that is parallel to the top surface of the substrate 100 and is orthogonal to the first direction D1. The third direction D3 may be a direction that is perpendicular to the top surface of the substrate 100. In other words, the third direction D3 may be orthogonal to the first direction D1 and the second direction D2.

The substrate 100 may include a semiconductor substrate or an insulating substrate. For example, the semiconductor substrate may be a silicon wafer, a silicon-germanium wafer, a germanium wafer, or an epitaxial layer grown on a single crystalline silicon wafer. In an embodiment, the insulating substrate may be one of sapphire, glass substrate, and plastic substrates.

The insulating layer 110 may be provided between the substrate 100 and the first semiconductor patterns 120 and the second semiconductor patterns 220. Although the insulating layer 110 is illustrated as a single layer, embodiments of the present disclosure are not limited to this example. For example, a plurality of the insulating layer 110 may be provided. The plurality of the insulating layer 110 may be provided to have at least two different thicknesses and may be formed of or include at least two different materials. For example, the insulating layer 110 may be formed of or include at least one from among silicon oxide, silicon nitride, and silicon oxynitride.

The first semiconductor patterns 120 may be vertically stacked on the insulating layer 110. Each of the first semiconductor patterns 120 may include a first impurity region 121, a second impurity region 123, and a channel region 125. The channel region 125 may be located between the first impurity region 121 and the second impurity region 123. The first impurity region 121 and the second impurity region 123 may be portions of the first semiconductor patterns 120, which are doped with impurities. For example, the first impurity region 121 and the second impurity region 123 may contain n-type or p-type impurities. For example, the channel region 125 of each of the first semiconductor patterns 120 may correspond to a channel region of at least one of the memory cells MC of FIG. 5. The first impurity region 121 and the second impurity region 123 may correspond to the source and drain terminals of the memory cells MC of FIG. 5. For example, the first semiconductor patterns 120 may correspond to the memory cells MC of FIG. 5 adjacent to each other in the third direction D3.

The first semiconductor patterns 120 may be spaced apart from each other in the third direction D3. An interlayer insulating pattern 127 and a portion of the first gate structure 130 may be between the first semiconductor patterns 120, which are adjacent to each other in the third direction D3. In detail, the interlayer insulating pattern 127 may be provided between a plurality of the first impurity region 121 of the first semiconductor patterns 120, which are adjacent to each other in the third direction D3 and between a plurality of the second impurity region 123. The interlayer insulating pattern 127 may be formed of or include at least one of insulating materials. Accordingly, the plurality of the first impurity region 121 or the plurality of the second impurity region 123 of the first semiconductor patterns 120, which are adjacent to each other in the third direction D3, may be electrically separated from each other. A portion of the first gate structure 130 may be provided between the plurality of the channel region 125 of the first semiconductor patterns 120, which are adjacent to each other in the third direction D3.

The first semiconductor patterns 120 may have a longitudinal axis extending in the first direction D1. For example, the first semiconductor patterns 120 may have a line, bar, or pillar shape, but embodiments of the present disclosure are not limited to this example.

The first gate structure 130 may be provided on the insulating layer 110 and may be on the top, bottom, and side surfaces of the first semiconductor patterns 120. In detail, the first gate structure 130 may be on a top surface 125t, a bottom surface 125b, and a side surface 125s of the channel region 125 of each of the first semiconductor patterns 120. Accordingly, a portion of the first gate structure 130 may be between a plurality of the channel region 125 of the first semiconductor patterns 120, which are adjacent to each other in the third direction D3. The first gate structure 130 may not be on top surfaces, bottom surfaces, and side surfaces of the first impurity region 121 and the second impurity region 123 of the first semiconductor patterns 120. That is, the first gate structure 130 may be in contact with the channel region 125 of the first semiconductor patterns 120 and may be spaced apart from the first impurity region 121 and the second impurity region 123. For example, the first gate structure 130 may correspond to one of the word lines WL of FIG. 5.

The first gate structure 130 may include a first gate electrode 131, a first ferroelectric layer 133, and a first gate insulating layer 135. The first ferroelectric layer 133 and the first gate insulating layer 135 may be between the first gate electrode 131 and the channel region 125 of at least one of the first semiconductor patterns 120 and may be in contact with them. The first ferroelectric layer 133 may be between the first gate electrode 131 and the first gate insulating layer 135. The first gate insulating layer 135 may be between the first ferroelectric layer 133 and the channel region 125 of at least one of the first semiconductor patterns 120. That is, the first ferroelectric layer 133 may be in contact with the first gate electrode 131, and the first gate insulating layer 135 may be in contact with the channel region 125 of at least one of the first semiconductor patterns 120.

The first gate electrode 131 may be formed of or include at least one from among doped semiconductor materials (e.g., doped silicon and doped germanium), conductive metal nitride materials (e.g., titanium nitride and tantalum nitride), metallic materials (e.g., tungsten, titanium, and tantalum), and metal-semiconductor compounds (e.g., tungsten silicide, cobalt silicide, and titanium silicide).

The first ferroelectric layer 133 may be formed of or include a ferroelectric material, which has a polarization property when an electric field is applied thereto. The ferroelectric material may be formed of a hafnium-containing dielectric material. For example, the ferroelectric material may include HfO₂, HfSiO₂ (or Si-doped HfO₂), HfAlO₂ (or Al-doped HfO₂), HfSiON, HfZnO, HfZrO₂, ZrO₂, ZrSiO₂, HfZrSiO₂, ZrSiON, LaAlO, HfDyO₂, or HfScO₂.

The first gate insulating layer 135 may be formed of or include at least one from among high-k dielectric materials, silicon oxide, silicon nitride, and silicon oxynitride, and may have a single- or multi-layered structure. In an embodiment, the high-k dielectric materials may include at least one from among hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

The second semiconductor patterns 220 may be spaced apart from the first semiconductor patterns 120 in the second direction D2 and may be provided on the insulating layer 110. The second semiconductor patterns 220 may have a structure and material that are substantially equal or similar to those of the first semiconductor patterns 120. That is, the second semiconductor patterns 220 may be stacked to be spaced apart from each other in the third direction D3 and may have a shape extending in the first direction D1. Each of the second semiconductor patterns 220 may include a first impurity region 221, a second impurity region 223, and a channel region 225 between the first impurity region 221 and the second impurity region 223. For example, the second semiconductor patterns 220 may correspond to others of the memory cells MC of FIG. 5, which are adjacent to each other in the third direction D3.

The second gate structure 230 may be spaced apart from the first gate structure 130 in the second direction D2 and may be provided on the insulating layer 110. The second gate structure 230 may have a structure and material that are substantially equal or similar to those of the first gate structure 130. That is, the second gate structure 230 may be on a top surface 225t, a bottom surface 225b, and a side surface 225s of the channel region 225 of each of the second semiconductor patterns 220 and may be spaced apart from the first impurity region 221 and the second impurity region 223 of the second semiconductor patterns 220. The second gate structure 230 may include a second gate electrode 231, a second ferroelectric layer 233, and a second gate insulating layer 235. The second gate structure 230 and the first gate structure 130 may be provided to have a symmetric shape in the second direction D2.

An insulating pattern 210 may be provided between the first semiconductor patterns 120 and the second semiconductor patterns 220 and between the first gate structure 130 and the second gate structure 230. Due to the insulating pattern 210, the first semiconductor patterns 120 and the first gate structure 130 may be electrically separated from the second semiconductor patterns 220 and the second gate structure 230. The first semiconductor patterns 120 and the second semiconductor patterns 220 may be symmetrical to each other with respect to the insulating pattern 210. The first gate structure 130 and the second gate structure 230 may be symmetrical to each other with respect to the insulating pattern 210. When measured in the first direction D1, a length of the insulating pattern 210 may be substantially equal to a length of the first semiconductor patterns 120 and/or a length of the second semiconductor patterns 220. When measured in the third direction D3, a height of the insulating pattern 210 may be substantially equal to a height of the first gate structure 130 and/or a height of the second gate structure 230. For example, the insulating pattern 210 may be formed of or include at least one from among silicon oxide, silicon nitride, and silicon oxynitride.

First conductive lines 310 may be provided on the insulating layer 110 and may be on side surfaces of the first semiconductor patterns 120, the second semiconductor patterns 220, and the insulating pattern 210. The first conductive lines 310 may be connected to the first impurity region 121 of the first semiconductor patterns 120 and the first impurity region 221 of the second semiconductor patterns 220. In other words, the first impurity region 121 of the first semiconductor patterns 120 and the first impurity region 221 of the second semiconductor patterns 220, which are located at the same height or level, may be connected in common to one of the first conductive lines 310. For example, the first conductive lines 310 may correspond to the bit lines BL of FIG. 5. The first conductive lines 310 may extend in the second direction D2 and may be spaced apart from each other in the third direction D3. The interlayer insulating pattern 127 may be between the first conductive lines 310, which are adjacent to each other in the third direction D3. Since the interlayer insulating pattern 127 includes an insulating material, the first conductive lines 310, which are adjacent to each other in the third direction D3, may be electrically separated from each other.

Second conductive lines 320 may be provided on the insulating layer 110 and may be on side surfaces of the first semiconductor patterns 120 and the second semiconductor patterns 220, which are opposite to the first conductive lines 310. For example, the second conductive lines 320 may be spaced apart from the first conductive lines 310. The first semiconductor patterns 120, the first gate structure 130, the second semiconductor patterns 220, and the second gate structure 230 may be between the second conductive lines 320 and the first conductive lines 310. Each of the second conductive lines 320 may be connected to the first semiconductor patterns 120 or the second semiconductor patterns 220. In detail, one of the second conductive lines 320 may be connected to the second impurity region 123 of the first semiconductor patterns 120. Another one of the second conductive lines 320 may be connected to the second impurity region 223 of the second semiconductor patterns 220. In other words, the first semiconductor patterns 120 may be connected in common to one of the second conductive lines 320. The second semiconductor patterns 220 may be connected in common to another one of the second conductive lines 320. For example, the second conductive lines 320 may correspond to the source lines SL of FIG. 5. The second conductive lines 320 may extend in the third direction D3 and may be spaced apart from each other in the second direction D2.

According to an embodiment of the present disclosure, the semiconductor device may include the first gate electrode 131 (or the second gate electrode 231), which is on the top surface 125t (or the top surface 225t), the bottom surface 125b (or the bottom surface 225b), and the side surface 125s (or the side surface 225s) of the channel region 125 (or the channel region 225). For example, the first gate electrode 131 (or the second gate electrode 231) may be used to control a current flowing through the channel region 125 or (the channel region 225) or through three surfaces of the channel region 125 (or the channel region 225). In addition, ferroelectric field effect transistors of the semiconductor device may be three-dimensionally arranged. Thus, the integration density and gate controllability of the semiconductor device may be improved.

Referring to FIG. 8, the channel region 125 of each of the first semiconductor patterns 120 may include the top surface 125t, the bottom surface 125b, a first side surface 125s1, and a second side surface 125s2. The top surface 125t and the bottom surface 125b may be opposite to each other in the third direction D3, and the first side surface 125s1 and the second side surface 125s2 may be opposite to each other in the second direction D2. For example, the first side surface 125s1 may be an outer side surface of the channel region 125 of the first semiconductor patterns 120, and the second side surface 125s2 may be an inner side surface of the channel region 125 of the first semiconductor patterns 120. The top surface 125t and the bottom surface 125b of a plurality of the channel region 125, which are adjacent to each other in the third direction D3, may face each other. The first gate structure 130 may be provided on the top surface 125t, the bottom surface 125b, and the first side surface 125s1 of the channel region 125. The top surface 125t, the bottom surface 125b, and the first side surface 125s1 of the channel region 125 may be in contact with the first gate insulating layer 135 of the first gate structure 130. The insulating pattern 210 may be provided on the second side surface 125s2 of the channel region 125. The second side surface 125s2 of the channel region 125 may be in contact with the insulating pattern 210.

The first gate electrode 131 of the first gate structure 130 may include a vertical portion VP and a horizontal portion HP. The vertical portion VP may extend on the first side surface 125s1 of the channel region 125 in the third direction D3. The channel region 125 may be located between the vertical portion VP and the insulating pattern 210. The horizontal portion HP may extend from the vertical portion VP in the second direction D2. That is, the horizontal portion HP may extend into a space between a plurality of the channel region 125, which are adjacent to each other in the third direction D3. Referring to FIG. 7A, the first gate electrode 131 may include a plurality of the horizontal portion HP, which are spaced apart from each other in the third direction D3. The channel region 125 may be between two of the horizontal portion HP, which are adjacent to each other in the third direction D3.

The first gate insulating layer 135 of the first gate structure 130 may be provided between the first ferroelectric layer 133 and the channel region 125, and between the first ferroelectric layer 133 and the insulating pattern 210. The first gate insulating layer 135 may extend in the second direction D2 and the third direction D3 to face the plurality of the channel region 125, which are adjacent to each other in the third direction D3, and the insulating pattern 210. A portion of the first gate insulating layer 135 may be in contact with the channel region 125 and the insulating pattern 210.

The first ferroelectric layer 133 of the first gate structure 130 may be provided between the first gate insulating layer 135 and the first gate electrode 131. The first ferroelectric layer 133 may extend in the second and third directions D2 and D3 to face the plurality of the channel region 125, which are adjacent to each other in the third direction D3, and the insulating pattern 210. That is, the first ferroelectric layer 133 may extend along the first gate insulating layer 135 to have a shape similar to a shape of the first gate insulating layer 135.

The first ferroelectric layer 133 may have a first thickness T1 in the second direction D2. The first ferroelectric layer 133 may have a second thickness T2 in the third direction D3. The first thickness T1 may be substantially equal to the second thickness T2. In other words, the first thickness T1 of the first ferroelectric layer 133 adjacent to the vertical portion VP may be substantially equal to the second thickness T2 of the first ferroelectric layer 133 adjacent to the horizontal portion HP. That is, the first ferroelectric layer 133 may have a constant thickness. The vertical portion VP of the first gate electrode 131 may have a third thickness T3 in the second direction D2. The horizontal portion HP of the first gate electrode 131 may have a fourth thickness T4 in the third direction D3. The fourth thickness T4 may be larger than the third thickness T3. That is, the first gate electrode 131 may not have a constant thickness, unlike the first ferroelectric layer 133.

Since the horizontal portion HP of the first gate electrode 131 is on the top surface 125t and the bottom surface 125b of the channel region 125, the channel region 125 may be overlapped with the horizontal portion HP, when viewed in a plan view. The channel region 125 may have a first length L1 in the second direction D2. When viewed in a plan view, a portion of the horizontal portion HP, which is overlapped with the channel region 125, may have a second length L2 in the second direction D2. The second length L2 may be smaller than the first length L1. For example, the second length L2 may be equal to or larger than half of the first length L1. That is, the channel region 125 may be overlapped with the horizontal portion HP by a length that is larger than half of the first length L1, when viewed in a plan view. Accordingly, the first gate electrode 131 may be used to control a current flowing through the channel region 125 or through the top surface 125t and the bottom surface 125b of the channel region 125. Thus, the gate controllability of the semiconductor device may be improved.

Hereinafter, other examples of the semiconductor device will be described below. However, for concise description, a previously described element may be identified by the same reference number without repeating an overlapping description thereof.

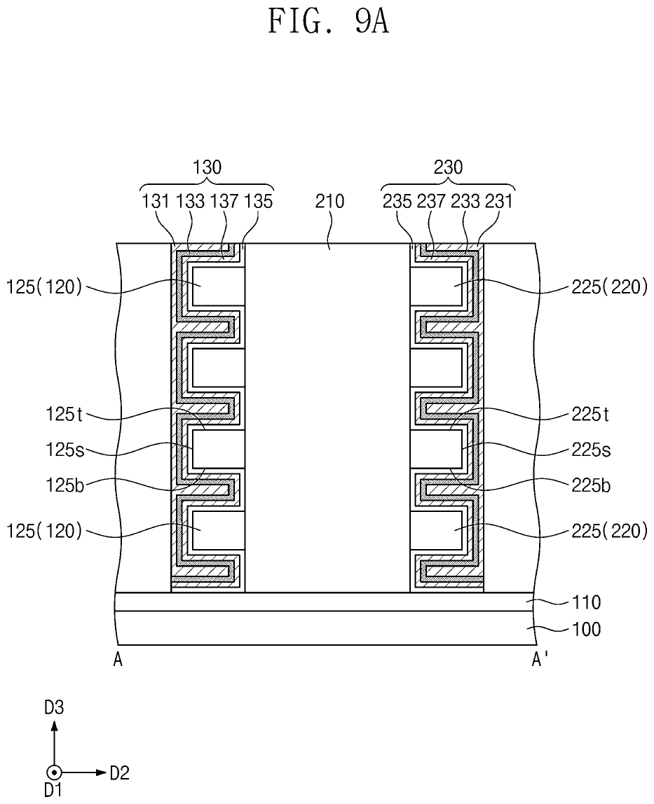

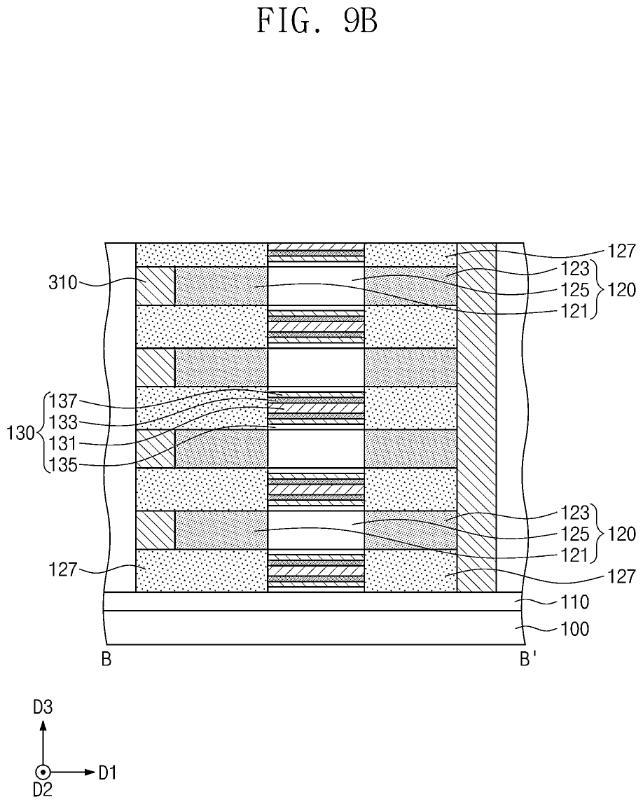

FIGS. 9A and 9B are sectional views, which are respectively taken along the lines A-A′ and B-B′ of FIG. 6 to illustrate a semiconductor device according to an embodiment of the present disclosure.

Referring to FIGS. 9A and 9B, the first gate structure 130 may further include a first metal pattern 137. The first metal pattern 137 may be between the first gate insulating layer 135 and the first ferroelectric layer 133. A portion of the first metal pattern 137 may be located between the plurality of the channel region 125 of the first semiconductor patterns 120, which are adjacent to each other in the third direction D3. The first metal pattern 137 may be on the top surface 125t, the bottom surface 125b, and the side surface 125s of the plurality of the channel region 125 of the first semiconductor patterns 120 and may extend in the second direction D2 and the third direction D3. That is, the first metal pattern 137 may extend along the first gate insulating layer 135 to have a shape similar to the shape of the first gate insulating layer 135. For example, the first metal pattern 137 may be formed of or include at least one of metallic materials (e.g., platinum) and/or metal oxide materials (e.g., RuO₂, IrO₂, and LaSrCoO₃). The first metal pattern 137 may be used to easily maintain the polarization property of the first ferroelectric layer 133. Thus, the electrical characteristics of the semiconductor device may be improved.

The second gate structure 230 may further include a second metal pattern 237. The second gate structure 230 may have a structure and material that are substantially equal or similar to those of the first gate structure 130. That is, the second metal pattern 237 may be between the second gate insulating layer 235 and the second ferroelectric layer 233 and may extend in a shape similar to the second gate insulating layer 235. Thus, the second gate structure 230 and the first gate structure 130 may be symmetrical to each other in the second direction D2.

However, embodiments of the present disclosure are not limited to this example. For example, only one of the first gate structure 130 and the second gate structure 230 may include the first metal pattern 137 or the second metal pattern 237.

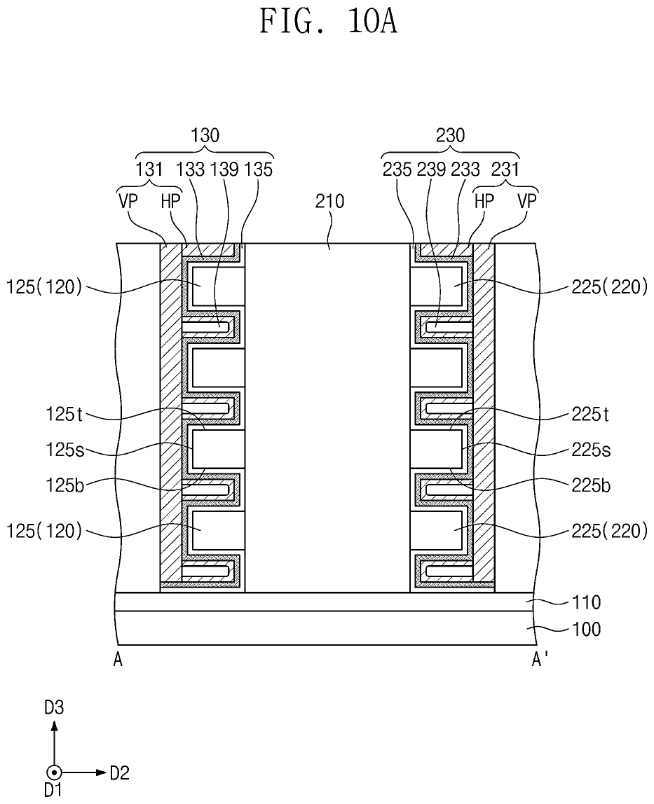

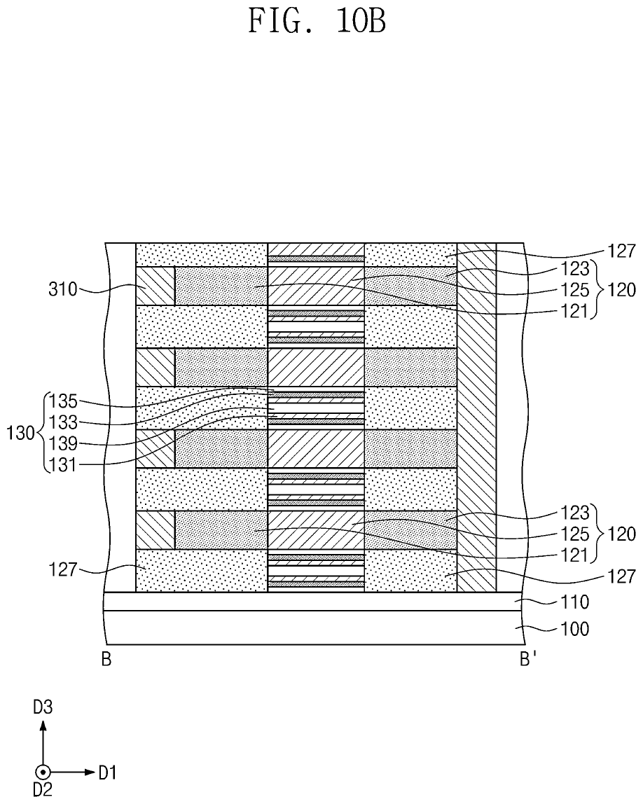

FIGS. 10A and 10B are sectional views, which are respectively taken along lines A-A′ and B-B′ of FIG. 6 to illustrate a semiconductor device according to an embodiment of the present disclosure.

Referring to FIGS. 10A and 10B, the first gate structure 130 may further include a first filling pattern 139. The first filling pattern 139 may be located in the horizontal portion HP of the first gate electrode 131. For example, the first filling pattern 139 may be between the plurality of the channel region 125 of the first semiconductor patterns 120, which are adjacent to each other in the third direction D3. The first filling pattern 139 may be spaced apart from the first ferroelectric layer 133. The horizontal portion HP of the first gate electrode 131 may cover the first ferroelectric layer 133 with a substantially uniform thickness. The vertical portion VP of the first gate electrode 131 may be in contact with a side surface of the first filling pattern 139 and the horizontal portion HP.

Since the first filling pattern 139 is formed in the horizontal portion HP, it may be possible to prevent a void or seam from being formed in the horizontal portion HP. Thus, the electrical characteristics of the semiconductor device may be improved. The first filling pattern 139 may be formed of or include at least one of insulating materials. For example, the insulating material may include silicon oxide, silicon nitride, and/or silicon oxynitride.

The second gate structure 230 may further include a second filling pattern 239. The second gate structure 230 may have a structure and material that are substantially equal or similar to those of the first gate structure 130. That is, the second filling pattern 239 may be in the horizontal portion HP of the second gate electrode 231 and may be spaced apart from the second ferroelectric layer 233. The second gate structure 230 and the first gate structure 130 may be symmetrical to each other in the second direction D2.

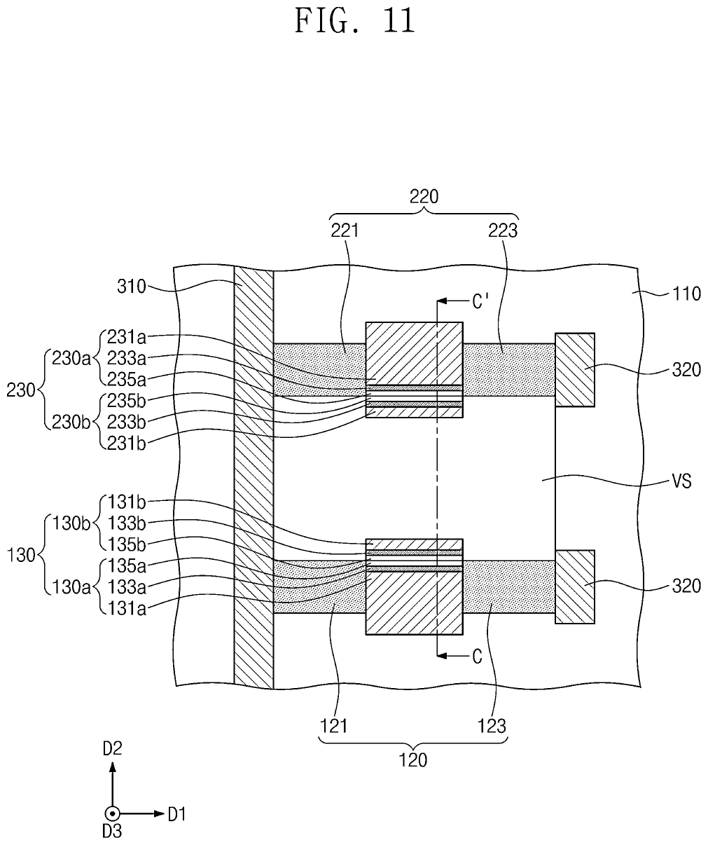

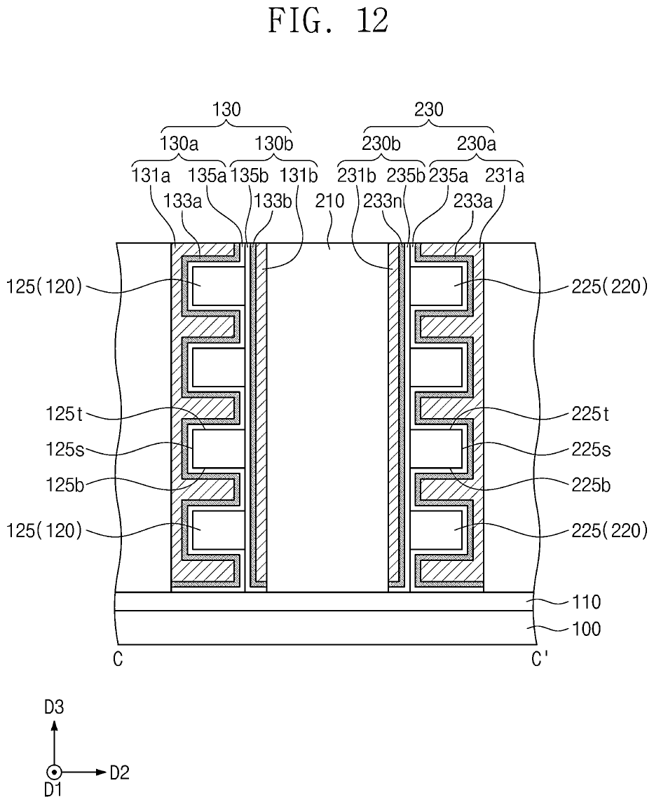

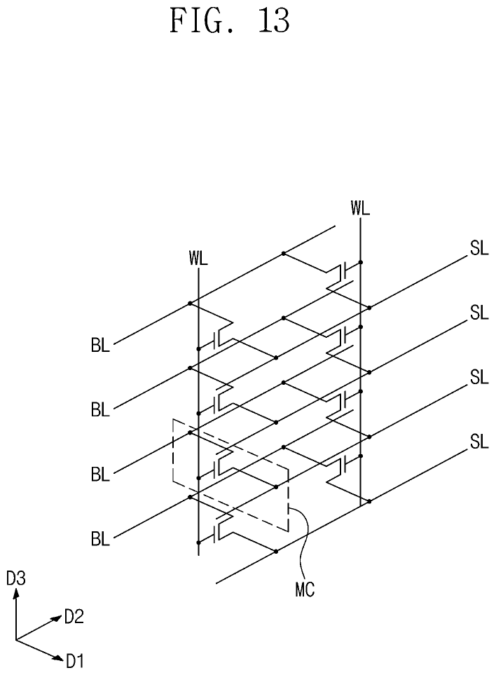

FIG. 11 is a plan view illustrating a semiconductor device according to an embodiment of the present disclosure. FIG. 12 is a sectional view, which is taken along a line C-C′ of FIG. 11 to illustrate a semiconductor device according to an embodiment of the present disclosure.

Referring to FIGS. 11 and 12, the first gate structure 130 may include a first outer gate structure 130a and a first inner gate structure 130b. The first outer gate structure 130a may include a first outer gate electrode 131a, a first outer ferroelectric layer 133a, and a first outer gate insulating layer 135a. The first outer gate structure 130a may be substantially the same as the first gate structure 130 described with reference to FIGS. 6 to 7B. That is, the first outer gate structure 130a may be on the top surface 125t, the bottom surface 125b, and the first side surface 125s1 of the channel region 125 of at least one of the first semiconductor patterns 120.

The first inner gate structure 130b may be between the first outer gate structure 130a and the insulating pattern 210. The channel region 125 of at least one of the first semiconductor patterns 120 may be between the first inner gate structure 130b and the first outer gate structure 130a. That is, the first inner gate structure 130b may be on the second side surface 125s2 of the channel region 125 of the first semiconductor patterns 120. The first inner gate structure 130b may extend in the third direction D3. Due to the first inner gate structure 130b, the channel region 125 of the first semiconductor patterns 120 may be spaced apart from the insulating pattern 210. When measured in the first direction D1, a width of the first inner gate structure 130b may be substantially equal to a width of the first outer gate structure 130a.

The first inner gate structure 130b may include a first inner gate electrode 131b, a first inner ferroelectric layer 133b, and a first inner gate insulating layer 135b. The first inner ferroelectric layer 133b may be between the first inner gate electrode 131b and the first inner gate insulating layer 135b. The first inner gate electrode 131b may be in contact with the insulating pattern 210. The first inner gate insulating layer 135b may be in contact with the channel region 125 of the first semiconductor patterns 120 and a portion of the first outer gate insulating layer 135a. The first inner gate electrode 131b, the first inner ferroelectric layer 133b, and the first inner gate insulating layer 135b may have the same width in the first direction D1. Each of the first inner gate electrode 131b, the first inner ferroelectric layer 133b, and the first inner gate insulating layer 135b may be formed of or include substantially the same material as a corresponding one of the first outer gate electrode 131a, the first outer ferroelectric layer 133a, and the first outer gate insulating layer 135a.

In other words, the first outer gate structure 130a and the first inner gate structure 130b may be on the top surface 125t, the bottom surface 125b, the first side surface 125s1, and the second side surface 125s2 of the channel region 125 of the first semiconductor patterns 120 to enclose the channel region 125 of the first semiconductor patterns 120. Furthermore, the first outer gate electrode 131a and the first inner gate electrode 131b may be applied with the same voltage. Accordingly, it may be possible to control a current flowing through the channel region 125 or through four surfaces of the channel region 125 of the first semiconductor patterns 120. Thus, the gate controllability of the semiconductor device may be improved, and this may make it possible to improve the electrical characteristics of the semiconductor device.

The second gate structure 230 may include a second outer gate structure 230a and a second inner gate structure 230b. The second outer gate structure 230a may include a second outer gate electrode 231a, a second outer ferroelectric layer 233a, and a second outer gate insulating layer 235a. The second outer gate structure 230a may be provided to have substantially the same features as those of the second gate structure 230 described with reference to FIGS. 6 to 7B.

The second inner gate structure 230b may have a structure and material that are substantially equal or similar to those of the first inner gate structure 130b. The second inner gate structure 230b may include a second inner gate electrode 231b, a second inner ferroelectric layer 233b, and a second inner gate insulating layer 235b. The second inner gate structure 230b may be between the second outer gate structure 230a and the insulating pattern 210 and may extend in the third direction D3. The second inner ferroelectric layer 233b may be between the second inner gate electrode 231b and the second inner gate insulating layer 235b.

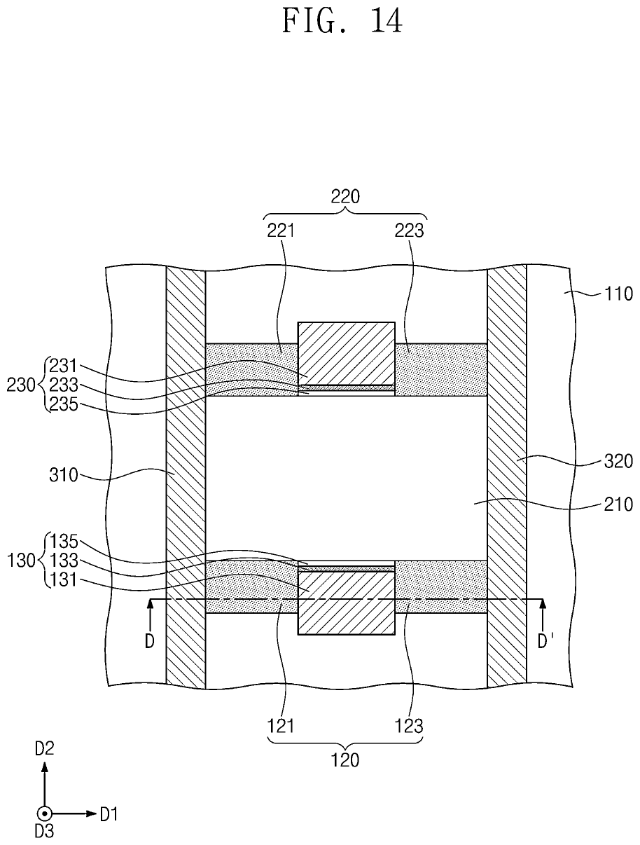

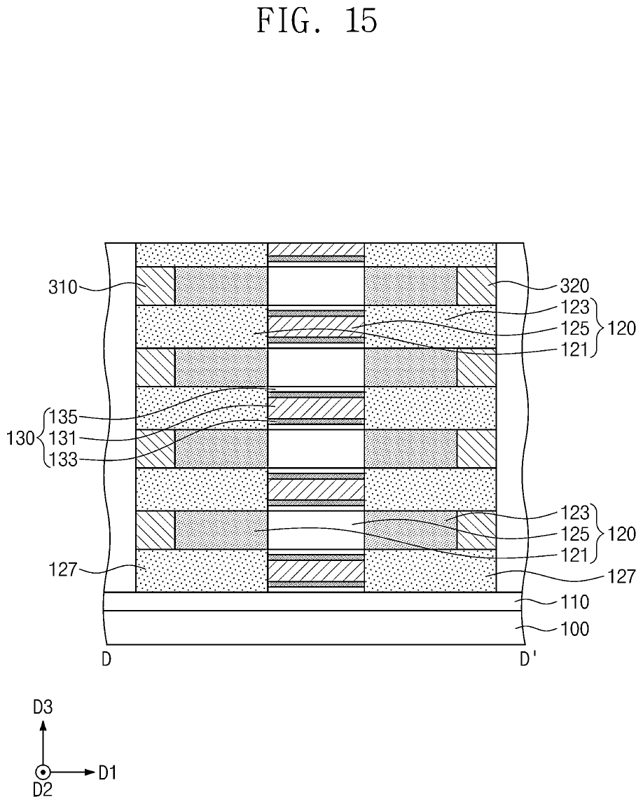

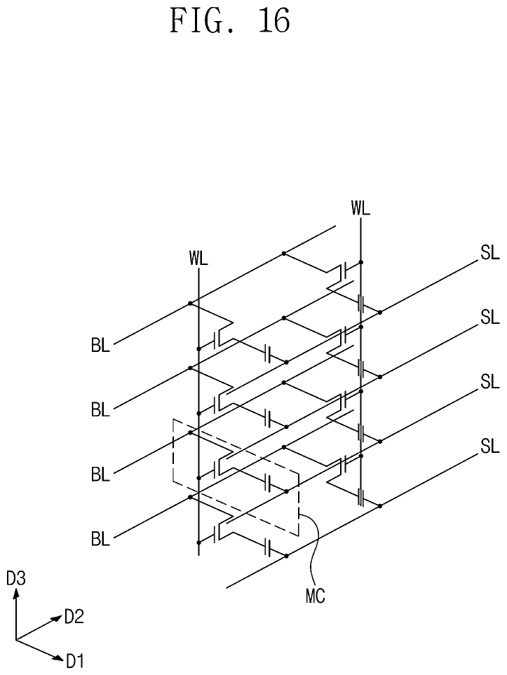

FIG. 13 is a circuit diagram illustrating a semiconductor device according to an embodiment of the present disclosure. FIG. 14 is a plan view illustrating a semiconductor device according to an embodiment of the present disclosure. FIG. 15 is a sectional view, which is taken along a line D-D′ of FIG. 14 to illustrate a semiconductor device according to an embodiment of the present disclosure.

Referring to FIG. 13, the source lines SL may extend in the second direction D2 parallel to each other. The source lines SL may be spaced apart from each other in the third direction D3. The source lines SL may correspond to the bit lines BL, respectively. In an embodiment, the memory cells MC, which are at the same height or level, may be connected in common to the same bit line BL and the same source line SL. The memory cells MC, which are at different heights, may be respectively connected to different bit lines BL and different source lines SL.

Referring to FIGS. 14 and 15, the second conductive lines 320 may be provided on the insulating layer 110. The second conductive lines 320 may be opposite to the first conductive lines 310 and may be on side surfaces of the first semiconductor patterns 120, the second semiconductor patterns 220, and the insulating pattern 210. For example, the first semiconductor patterns 120, the second semiconductor patterns 220, and the insulating pattern 210 may be provided between the first conductive lines 310 and the second conductive lines 320.

The second conductive lines 320 may be connected to the second impurity region 123 of the first semiconductor patterns 120 and the second impurity region 223 of the second semiconductor patterns 220. Similar to the first conductive lines 310, the second impurity region 123 of the first semiconductor patterns 120 and the second impurity region 223 of the second semiconductor patterns 220, which are located at the same height or level, may be connected in common to one of the second conductive lines 320. For example, the second conductive lines 320 may correspond to the source lines SL of FIG. 5.

The second conductive lines 320 may extend in the second direction D2 and may be spaced apart from each other in the third direction D3. The plurality of the interlayer insulating pattern 127 may be between the second conductive lines 320, which are adjacent to each other in the third direction D3. Since the plurality of the interlayer insulating pattern 127 includes an insulating material, the second conductive lines 320, which are adjacent to each other in the third direction D3, may be electrically separated from each other.

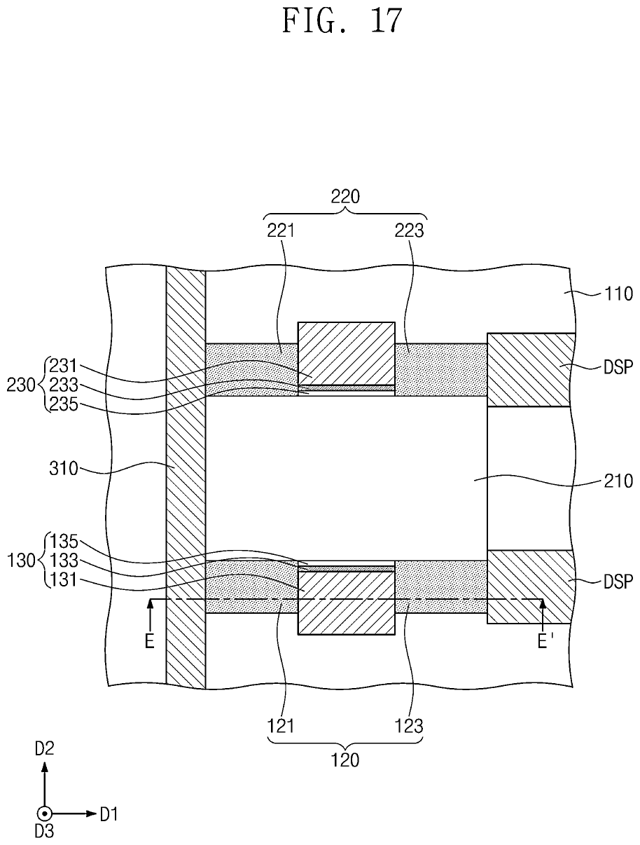

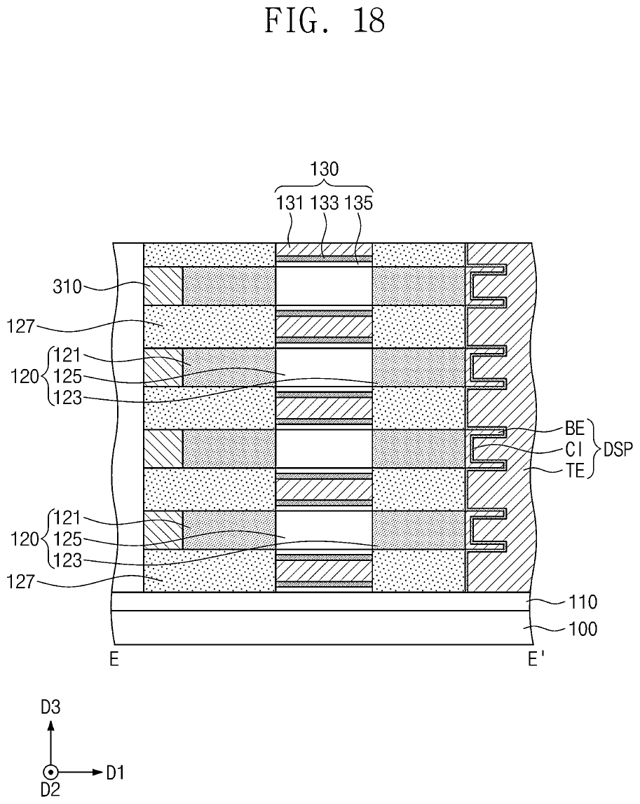

FIG. 16 is a circuit diagram illustrating a semiconductor device according to an embodiment of the present disclosure. FIG. 17 is a plan view illustrating a semiconductor device according to an embodiment of the present disclosure. FIG. 18 is a sectional view, which is taken along a line E-E′ of FIG. 17 to illustrate a semiconductor device according to an embodiment of the present disclosure.

Referring to FIG. 16, each of the memory cells MC may include a data storage device. For example, the data storage device may include a capacitor. The data storage device may be controlled by voltages, which are respectively applied to the source and drain terminals and the channel region of the memory cell MC. The data storage device may be configured to store data.

Referring to FIGS. 17 and 18, the semiconductor device may further include data storing patterns DSP. The data storing patterns DSP may be provided on the insulating layer 110. The data storing patterns DSP may be on side surfaces of the first semiconductor patterns 120 and the second semiconductor patterns 220, which are spaced apart from the first conductive lines 310. That is, the first semiconductor patterns 120 and the second semiconductor patterns 220 may be between the data storing patterns DSP and the first conductive lines 310. The data storing patterns DSP may be respectively connected to the second impurity region 123 of the first semiconductor patterns 120 and the second impurity region 223 of the second semiconductor patterns 220.

The data storing patterns DSP may include a bottom electrode BE, a capacitor dielectric layer CI, and a top electrode TE. The data storing patterns DSP may be configured to store electrical charges in the capacitor dielectric layer CI using a potential difference, which is produced between the top electrode TE and the bottom electrode BE. For example, the data storing patterns DSP may correspond to the data storage device of FIG. 16. The bottom electrode BE may be connected to the second impurity region 123 of at least one of the first semiconductor patterns 120. The bottom electrode BE may be provided in the form of a hollow cylinder, but embodiments of the present disclosure are not limited to this example. For example, the bottom electrode BE may be provided in the form of a solid cylinder.

The capacitor dielectric layer CI may be provided on the bottom electrode BE and the interlayer insulating pattern 127. The capacitor dielectric layer CI may extend along a surface of the bottom electrode BE and a side surface of the interlayer insulating pattern 127. The capacitor dielectric layer CI may have a constant thickness. For example, the capacitor dielectric layer CI may be formed of or include a ferroelectric material exhibiting a polarization property. The ferroelectric material may be formed of a hafnium-containing dielectric material. For example, the ferroelectric material may include HfO₂, HfSiO₂ (or Si-doped HfO₂), HfAlO₂ (or Al-doped HfO₂), HfSiON, HfZnO, HfZrO₂, ZrO₂, ZrSiO₂, HfZrSiO₂, ZrSiON, LaAlO, HfDyO₂, or HfScO₂.

The top electrode TE may be provided on the capacitor dielectric layer CI. The top electrode TE may cover the capacitor dielectric layer CI. In other words, the capacitor dielectric layer CI may be between the top electrode TE and the bottom electrode BE. The top electrode TE and the bottom electrode BE may be formed of or include at least one of conductive materials. For example, the conductive material may be one of doped semiconductor materials (doped silicon, doped silicon-germanium, and so forth), conductive metal nitrides (titanium nitride, tantalum nitride, and so forth), metallic materials (tungsten, titanium, tantalum, and so forth), and metal-semiconductor compounds (tungsten silicide, cobalt silicide, titanium silicide, and so forth).

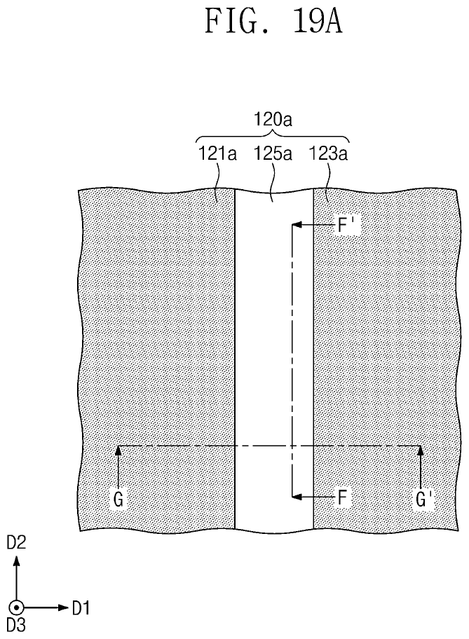

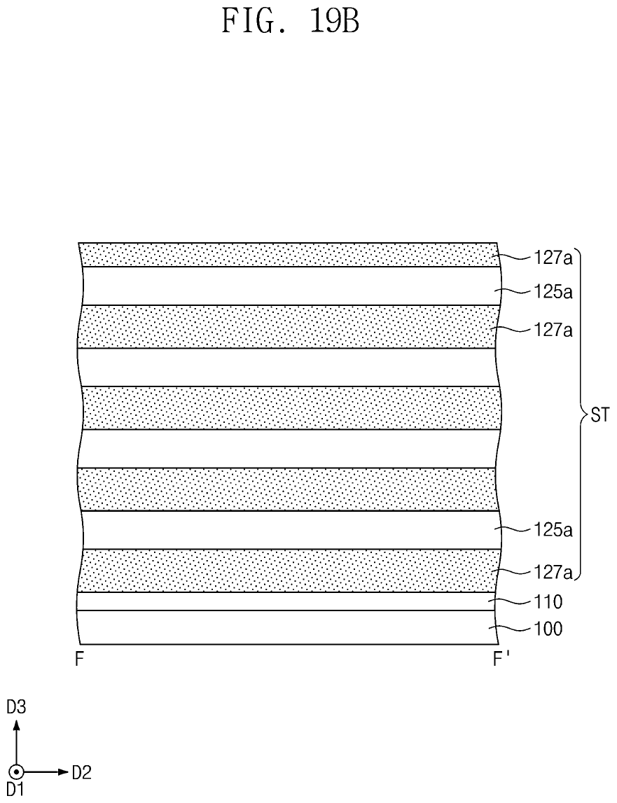

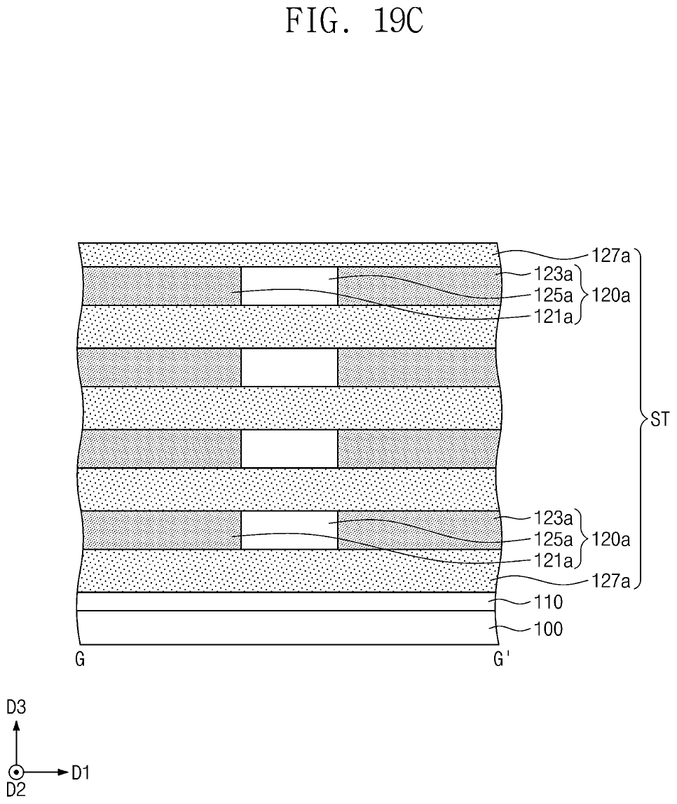

FIGS. 19A to 24B are diagrams illustrating a method of fabricating a semiconductor device, according to an embodiment of the present disclosure.

Referring to FIGS. 19A, 19B (sectional view taken along line F-F′ of FIG. 19A), and 19C (sectional view taken along line G-G′ of FIG. 19A), the substrate 100 may be provided. The substrate 100 may be one of a semiconductor substrate (e.g., a silicon wafer), an insulating substrate (e.g., a glass substrate), or a semiconductor or conductor layer covered with an insulating material.

The insulating layer 110 and a stack structure ST may be formed on the substrate 100. The insulating layer 110 may be between the substrate 100 and the stack structure ST. The insulating layer 110 may have a constant thickness. The stack structure ST and the substrate 100 may be electrically separated from each other by the insulating layer 110. The insulating layer 110 may serve as an etch stop layer.

The stack structure ST may be formed on the insulating layer 110. The formation of the stack structure ST may include alternatively stacking a plurality of semiconductor layers 120a and a plurality of interlayer insulating layers 127a on the insulating layer 110 in the third direction D3. The interlayer insulating layers 127a and the semiconductor layers 120a may be formed by a deposition process. For example, the deposition process may include a chemical vapor deposition (CVD) process and an atomic layer deposition (ALD) process. One of the interlayer insulating layers 127a and one of the semiconductor layers 120a may be formed in an in-situ manner.

The semiconductor layers 120a may include first preliminary impurity regions 121a, second preliminary impurity regions 123a, and a plurality of a preliminary channel region 125a. The preliminary channel region 125a may be between the first preliminary impurity regions 121a and the second preliminary impurity regions 123a. The preliminary channel region 125a may extend in the second direction D2. The first preliminary impurity regions 121a and the second preliminary impurity regions 123a may be portions of the semiconductor layers 120a that are doped with impurities. The preliminary channel region 125a may be a portion of the semiconductor layers 120a that is not doped with impurities. The first preliminary impurity regions 121a and the second preliminary impurity regions 123a may be formed by performing an ion implantation process on the semiconductor layers 120a. For example, the first preliminary impurity regions 121a and the second preliminary impurity regions 123a may contain n-type or p-type impurities.

In an embodiment, the semiconductor layers 120a may be formed of or include an undoped or intrinsic semiconductor material. In this case, impurity regions may be formed after forming the first gate structure 130 and the second gate structure 230, which will be described below.

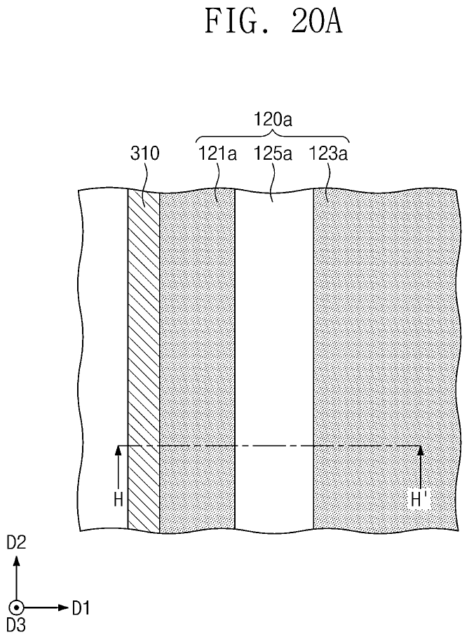

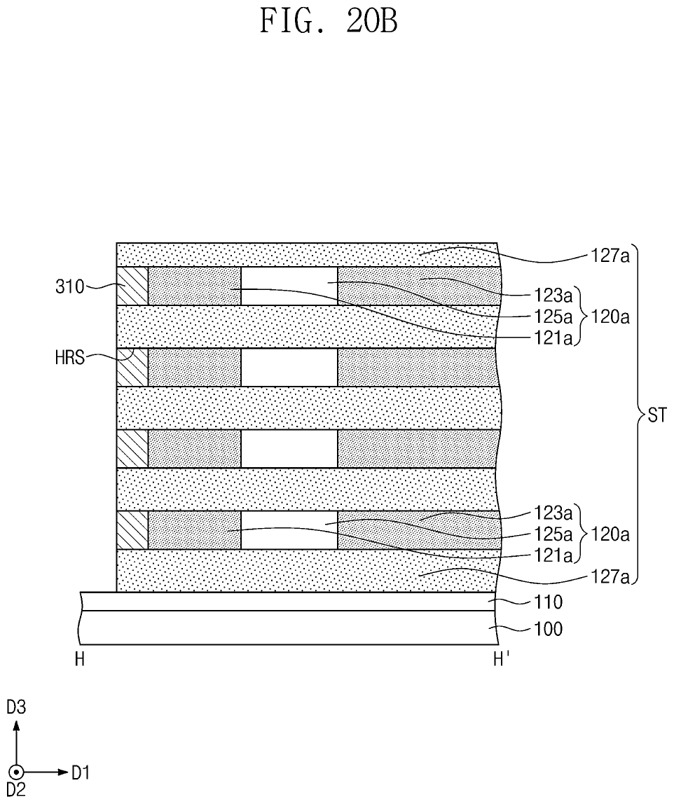

Referring to FIGS. 20A and 20B (sectional view taken along line H-H′ of FIG. 20A), the first conductive lines 310 may be formed on side surfaces of the first preliminary impurity regions 121a to extend in the second direction D2. The formation of the first conductive lines 310 may include etching the stack structure ST to expose a side surface of the stack structure ST, selectively removing portions of the first preliminary impurity regions 121a, and forming and patterning a conductive layer on the side surfaces of the first preliminary impurity regions 121a.

A mask may be formed on the stack structure ST, and then, an anisotropic etching process using the mask may be performed to etch the stack structure ST. As a result, a portion of the stack structure ST may be removed such that a side surface of the stack structure ST is exposed to the outside.

Thereafter, an etching process may be performed using an etch recipe, which is chosen to have an etch selectivity with respect to the interlayer insulating layers 127a and the first preliminary impurity regions 121a. The etching process may be performed to selectively etch the first preliminary impurity regions 121a, and not the interlayer insulating layers 127a. That is, the first preliminary impurity regions 121a may be partially removed through the exposed side surface of the stack structure ST. Accordingly, a horizontal recess region HRS may be formed between the interlayer insulating layers 127a.

Next, a conductive layer may be formed on the side surfaces of the first preliminary impurity regions 121a. The conductive layer may fill the horizontal recess region HRS. The conductive layer may be patterned to form the first conductive lines 310, which are spaced apart from each other in the third direction D3. That is, each of the first conductive lines 310 may be between the interlayer insulating layers 127a, which are adjacent to each other in the third direction D3.

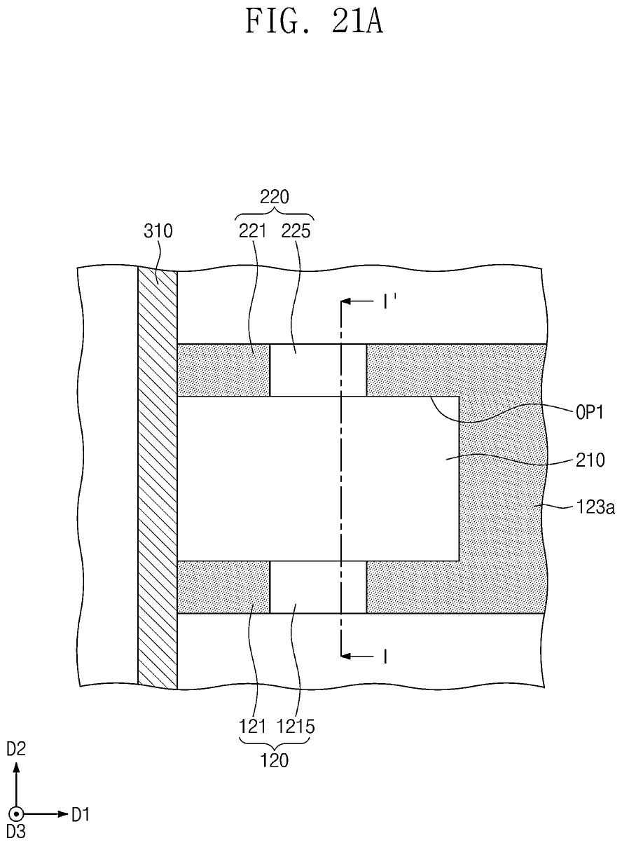

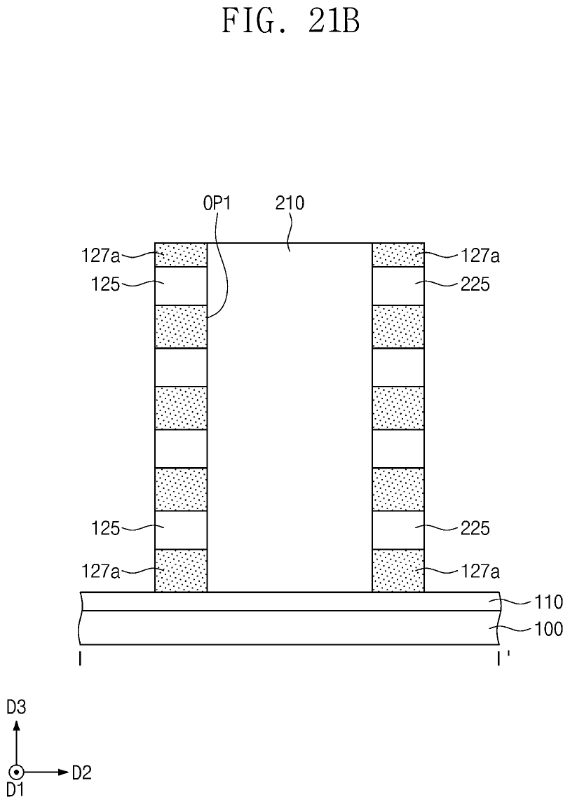

Referring to FIGS. 21A and 21B (sectional view taken along line I-I′ of FIG. 21A), the insulating pattern 210 and portions of the first semiconductor patterns 120 and the second semiconductor patterns 220 may be formed. The formation of the insulating pattern 210 may include forming a first opening OP1 to penetrate the stack structure ST and filling the first opening OP1 with an insulating material. The portions of the first semiconductor patterns 120 and the second semiconductor patterns 220 may be formed by patterning the stack structure ST.

The formation of the first opening OP1 may include forming a mask on the stack structure ST to have an opening corresponding to the first opening OP1 and performing an anisotropic etching process using the mask. The first opening OP1 may be formed to expose a portion of a top surface of the insulating layer 110. When viewed in a plan view, the first opening OP1 may not be overlapped with the first conductive lines 310. Thereafter, the first opening OP1 may be filled with an insulating material, and a planarization process may be performed on the insulating material. Thus, the insulating pattern 210 may be formed in the first opening OPT.

Next, the stack structure ST may be patterned to form the portions of the first semiconductor patterns 120 and the second semiconductor patterns 220. For example, the first preliminary impurity regions 121a may be patterned to form the first impurity region 121 and the first impurity region 221 of the first semiconductor patterns 120 and the second semiconductor patterns 220. The preliminary channel region 125a may be patterned to form the channel region 125 and the channel region 225 of the first semiconductor patterns 120 and the second semiconductor patterns 220. The second preliminary impurity regions 123a may also be patterned but may not form the second impurity region 123 and the second impurity region 223 of the first semiconductor patterns 120 and the second semiconductor patterns 220 (e.g., see FIG. 6).

In an embodiment, the entirety of the first semiconductor patterns 120 and the second semiconductor patterns 220 may be formed by patterning the stack structure ST at one time. For example, the second impurity region 123 and the second impurity region 223 of the first semiconductor patterns 120 and the second semiconductor patterns 220 (e.g., see FIG. 6) may be formed by patterning the second preliminary impurity regions 123a.

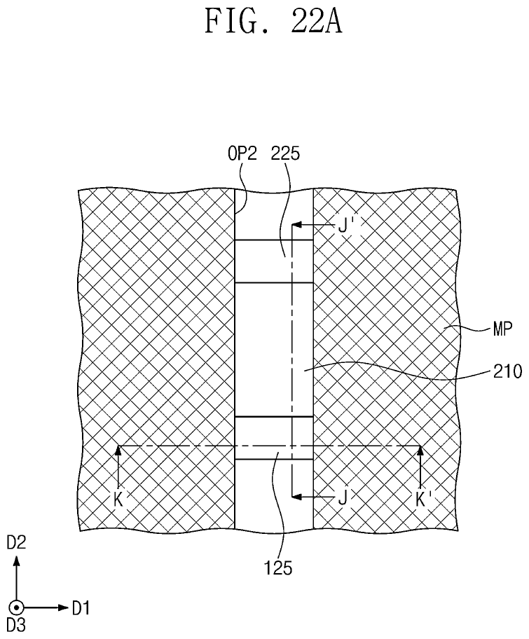

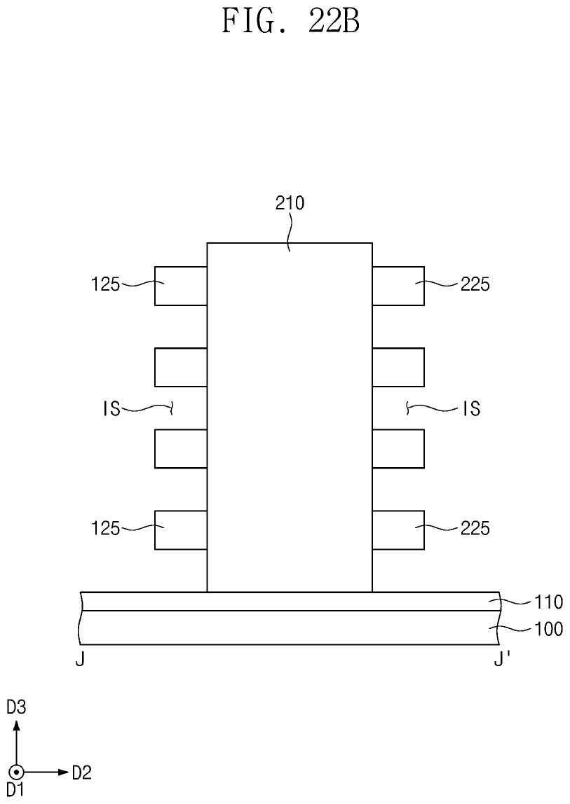

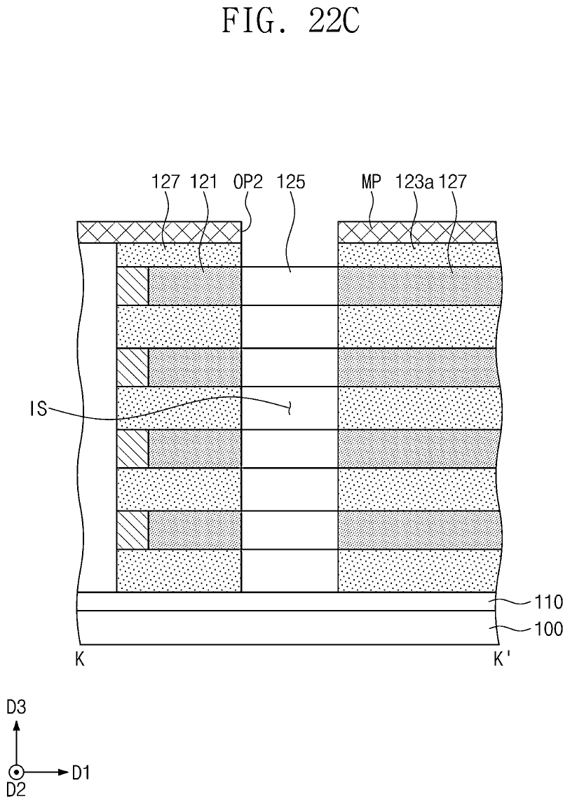

Referring to FIGS. 22A, 22B (sectional view taken along line J-J′ of FIG. 22A), and 22C (sectional view taken along line K-K′ of FIG. 22A), an interlayer insulating pattern and an internal space may be formed. In detail, a mask pattern MP having a second opening OP2 may be formed on the insulating layer 110. The second opening OP2 of the mask pattern MP may extend in the second direction D2. The second opening OP2 of the mask pattern MP may be formed to expose the channel region 125 and the channel region 225 of the first semiconductor patterns 120 and the second semiconductor patterns 220 and a portion of the insulating pattern 210.

Thereafter, an etching process may be performed to remove a portion of the interlayer insulating layers 127a. For example, the etching process may be a dry or wet etching process, which is chosen to have an etch selectivity between the first semiconductor patterns 120 and the second semiconductor patterns 220 and the interlayer insulating layers 127a. The plurality of the interlayer insulating pattern 127 may be formed by removing the portion of the interlayer insulating layers 127a through the second opening OP2 of the mask pattern MP. The interlayer insulating pattern 127 may be between a plurality of the first impurity region 121 or the second preliminary impurity regions 123a, which are adjacent to each other in the third direction D3. The interlayer insulating pattern 127 may not be provided between the plurality of the channel region 125, which are adjacent to each other in the third direction D3. That is, an internal space IS may be formed between the plurality of the interlayer insulating pattern 127, which are located at the same height or level. The internal space IS may be provided between the plurality of the channel region 125, which are adjacent to each other in the third direction D3.

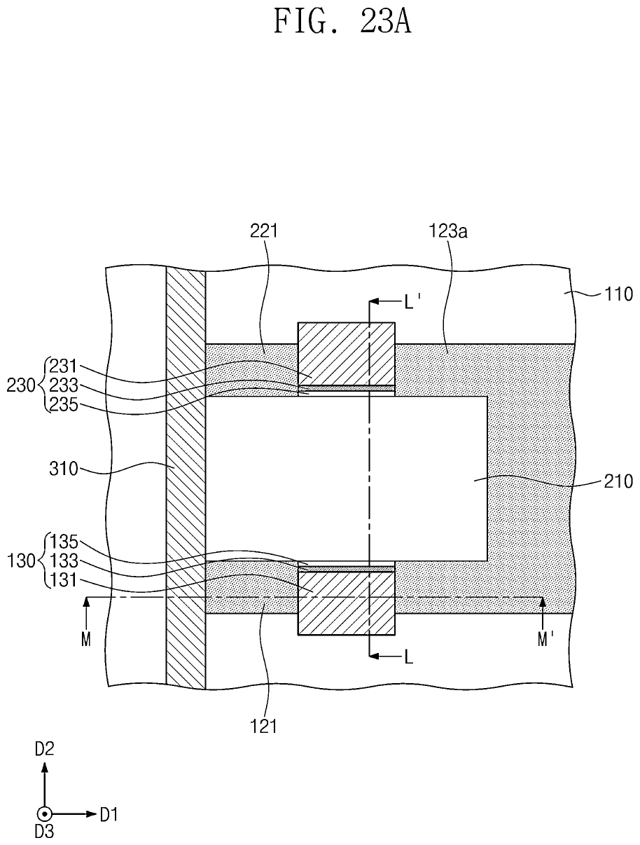

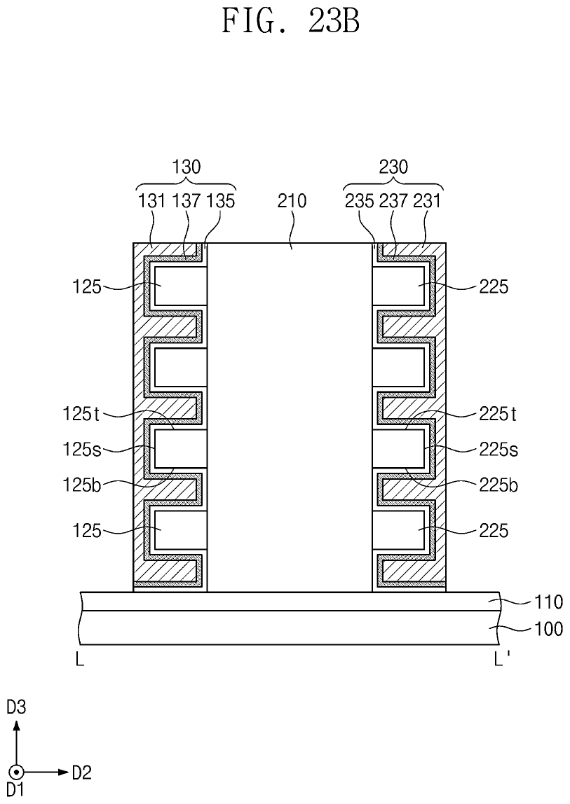

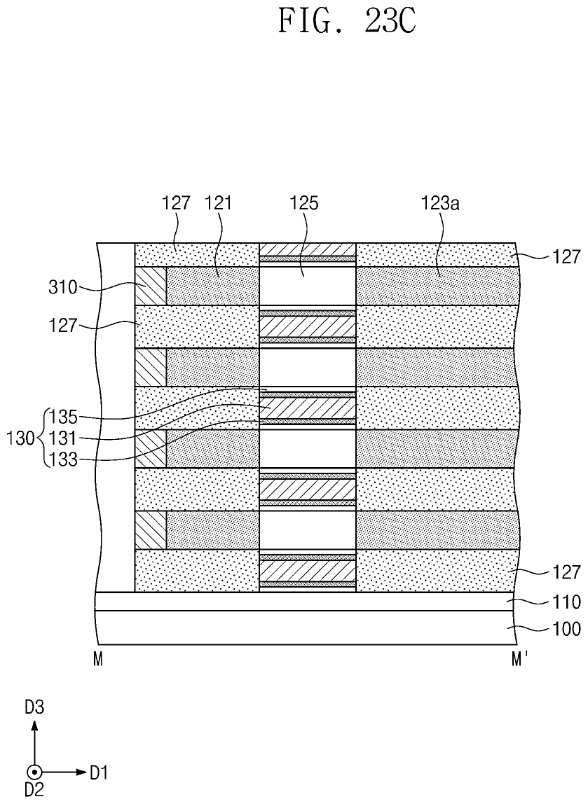

Referring to FIGS. 23A, 23B (sectional view taken along line L-L′ of FIG. 23A), and 23C (sectional view taken along line M-M′ of FIG. 23A), the first gate structure 130 and the second gate structure 230 may be formed. The formation of the first gate structure 130 and the second gate structure 230 may include forming a preliminary gate structure and performing a planarization process on the preliminary gate structure.

The formation of the preliminary gate structure may include sequentially forming a gate insulating layer, a ferroelectric layer, and a gate electrode. The gate insulating layer may be formed to conformally cover the top, bottom, and side surfaces of the channel region 125 and the channel region 225 of the first semiconductor patterns 120 and the second semiconductor patterns 220 and the insulating pattern 210, which is exposed by the second opening OP2 of the mask pattern MP. The ferroelectric layer may be conformally formed on the gate insulating layer. That is, the ferroelectric layer may be formed on the top, bottom, and side surfaces of the channel region 125 and the channel region 225 of the first semiconductor patterns 120 and the second semiconductor patterns 220 and the insulating pattern 210, which is exposed by the second opening OP2 of the mask pattern MP. The gate electrode may be formed on the ferroelectric layer. In other words, the preliminary gate structure may fill the internal space IS and be provided on the top, bottom, and side surfaces of the channel region 125 and the channel region 225 of the first semiconductor patterns 120 and the second semiconductor patterns 220.

Thereafter, a planarization process may be performed. The preliminary gate structure on the insulating pattern 210 may be removed by the planarization process. As a result of the planarization process, a top surface of the insulating pattern 210 may be exposed to the outside. As a result of the removal of the gate insulating layer on the insulating pattern 210, the first gate insulating layer 135 and the second gate insulating layer 235 may be formed. As a result of the removal of the ferroelectric layer on the insulating pattern 210, the first ferroelectric layer 133 and the second ferroelectric layer 233 may be formed. As a result of the removal of the gate electrode on the insulating pattern 210, the first gate electrode 131 and the second gate electrode 231 may be formed. In other words, the preliminary gate structure may form the first gate structure 130 and the second gate structure 230, which are spaced apart from each other in the second direction D2.

In an embodiment, the formation of the preliminary gate structure may further include forming a metal pattern. The metal pattern may be formed between the ferroelectric layer and the gate insulating layer. That is, the gate insulating layer, the metal pattern, the ferroelectric layer, and the gate electrode may be sequentially formed.

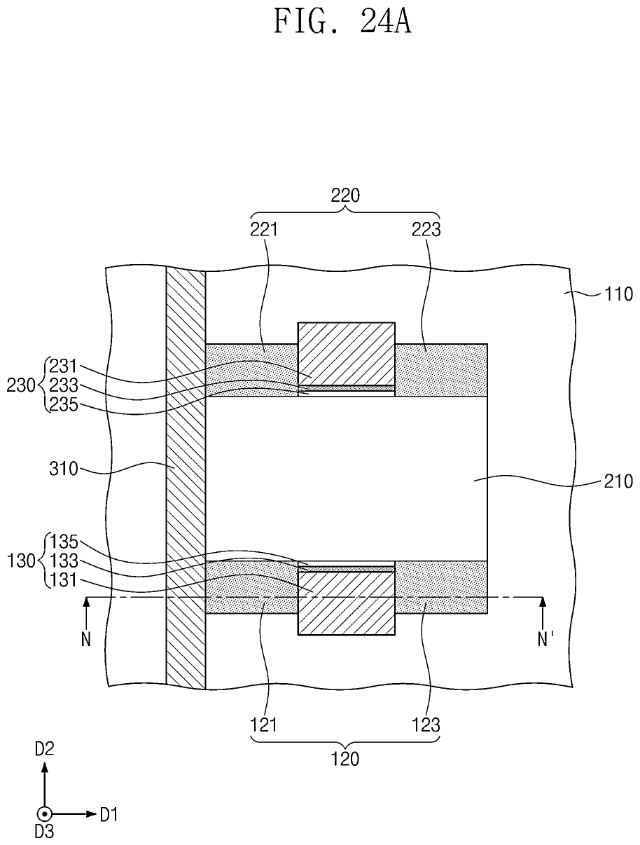

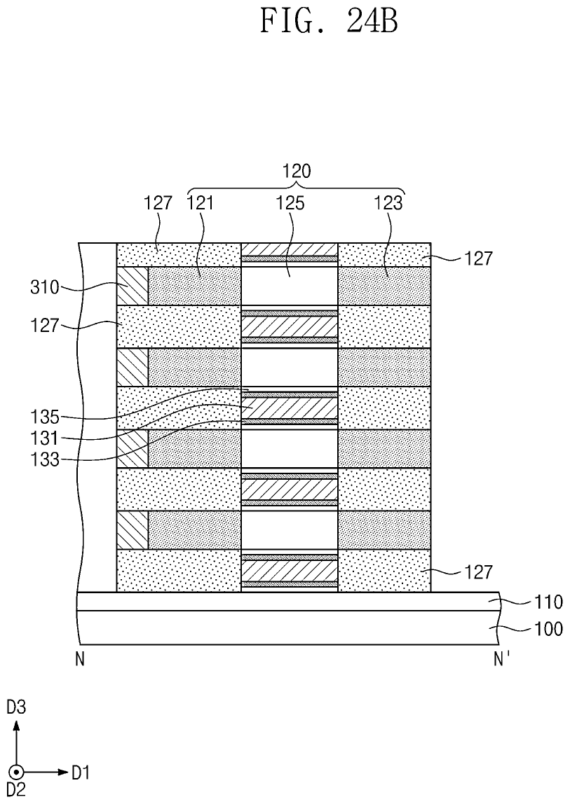

Referring to FIGS. 24A and 24B (sectional view taken along line N-N′ of FIG. 24A), the second impurity region 123 of the first semiconductor patterns 120 and the second impurity region 223 of the second semiconductor patterns 220 may be formed. A mask, which corresponds to the second impurity region 123 and the second impurity region 223 of the first semiconductor patterns 120 and the second semiconductor patterns 220, may be formed on the second preliminary impurity regions 123a. An anisotropic etching process using the mask may be performed to remove a portion of the second preliminary impurity regions 123a. For example, the second preliminary impurity regions 123a may be patterned to form the second impurity region 123 of the first semiconductor patterns 120 and the second impurity region 223 of the second semiconductor patterns 220, which are spaced apart from each other in the second direction D2.

Referring to FIGS. 6, 7A, and 7B, the second conductive lines 320, which are extended in the third direction D3 and are connected to the second impurity region 123 of the first semiconductor patterns 120 and the second impurity region 223 of the second semiconductor patterns 220, may be formed.

The formation of the second conductive lines 320 may include forming a conductive layer to cover side surfaces of the second impurity region 123 and the second impurity region 223 of the first semiconductor patterns 120 and the second semiconductor patterns 220 and patterning the conductive layer to form the second conductive lines 320, which are spaced apart from each other in the second direction D2.

In a semiconductor fabrication process according to an embodiment of the present disclosure, ferroelectric field effect transistors, which are three-dimensionally arranged, may be formed at the same time. Accordingly, the semiconductor fabrication process may be simplified.

Hereinafter, other examples of the semiconductor fabrication method will be described below. However, for concise description, a previously described element may be identified by the same reference number without repeating an overlapping description thereof.

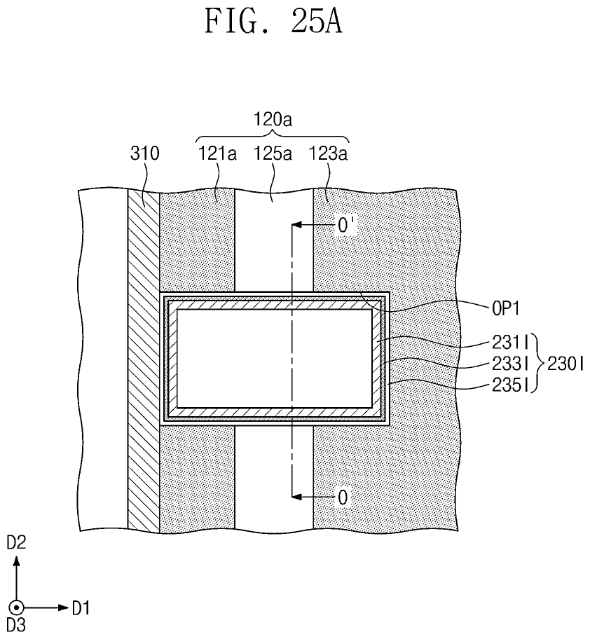

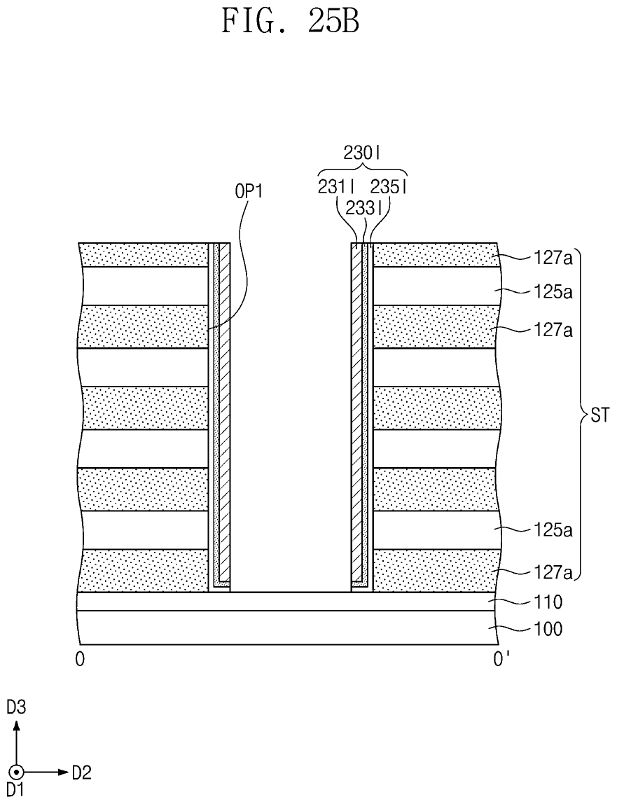

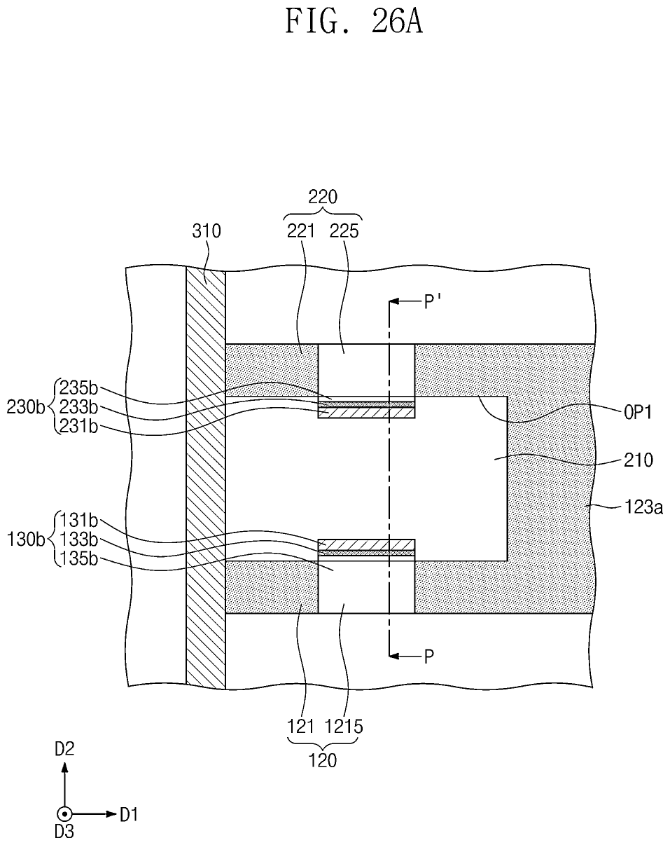

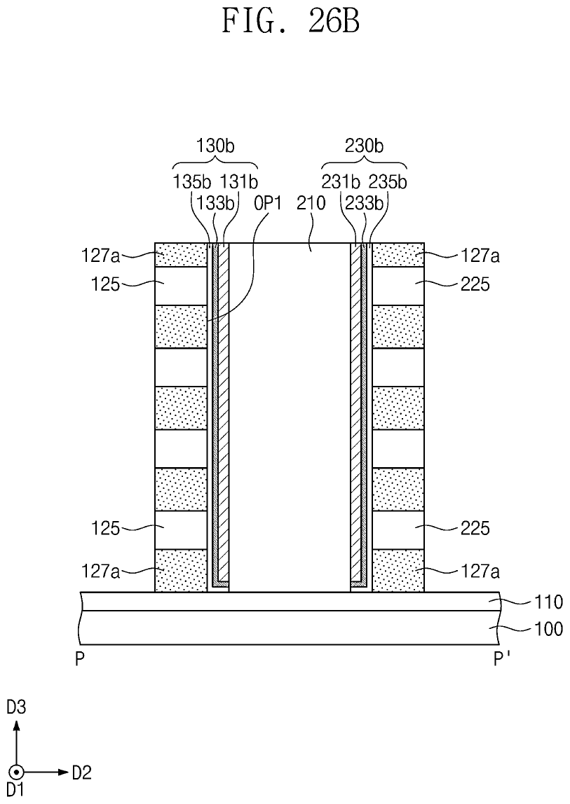

FIGS. 25A to 26B are diagrams illustrating a method of fabricating a semiconductor device, according to an embodiment of the present disclosure.

Referring to FIGS. 25A and 25B (sectional view taken along line O-O′ of FIG. 25A), a preliminary inner gate structure 2301 may be formed in the first opening OP1 penetrating the stack structure ST. The insulating layer 110, the stack structure ST, the first conductive lines 310, and the first opening OP1 may be formed by substantially the same method as that in the embodiment described with reference to FIGS. 19A to 21B.

The formation of the preliminary inner gate structure 2301 may include forming a preliminary inner gate insulating layer 2351, a preliminary inner ferroelectric layer 2331, and a preliminary inner gate electrode 2311 and exposing the top surface of the insulating layer 110 in the first opening OP1. The preliminary inner gate insulating layer 2351, the preliminary inner ferroelectric layer 2331, and the preliminary inner gate electrode 2311 may be sequentially and conformally formed on an inner surface of the first opening OPT. Next, the preliminary inner gate structure 2301 may be anisotropically etched to expose the top surface of the insulating layer 110 at a bottom level of the first opening OPT. When viewed in a plan view, the preliminary inner gate structure 2301 may have a closed shape.

Referring to FIGS. 26A and 26B (sectional view taken along line P-P′ of FIG. 26A), a portion of the preliminary inner gate structure 2301 may be patterned to form the first inner gate structure 130b and the second inner gate structure 230b.

A mask, which is extended in the second direction D2 to cross the first opening OP1, may be formed on the preliminary inner gate structure 2301. The mask may be located on the preliminary channel region 125a. A portion of the preliminary inner gate structure 2301, which is exposed by the mask, may be removed by an anisotropic etching process. Thus, a portion of the preliminary inner gate structure 2301, which is in contact with the first preliminary impurity regions 121a and the second preliminary impurity regions 123a, may be selectively removed to leave the other portion of the preliminary inner gate structure 2301, which is in contact with the preliminary channel region 125a. As a result, the first inner gate structure 130b and the second inner gate structure 230b may be formed to be in contact with the preliminary channel region 125a.

Thereafter, the insulating pattern 210, the first impurity region 121 and the first impurity region 221, and the channel region 125 and the channel region 225 of the first semiconductor patterns 120 and the second semiconductor patterns 220 may be formed by, for example, substantially the same method as that in the embodiment described with reference to FIGS. 21A and 22A.

Referring to FIGS. 11 and 12, the first outer gate structure 130a, the second outer gate structure 230a, and the second conductive lines 320 may be formed. The formation of the first outer gate structure 130a and the second outer gate structure 230a may be substantially the same as the formation of the first gate structure 130 and the second gate structure 230 described with reference to FIGS. 23A to 23C.

According to an embodiment of the present disclosure, by three-dimensionally arranging unit memory cells composed of ferroelectric field effect transistors, it may be possible to realize a semiconductor device having a nonvolatile property and a high operation speed. In addition, a gate electrode may be provided on top, bottom, and side surfaces of a channel region, and in this case, the gate controllability may be improved. Accordingly, it may be possible to realize a highly-integrated semiconductor memory device with improved electrical characteristics.

While example embodiments of the present disclosure have been particularly shown and described, it will be understood by one of ordinary skill in the art that variations in form and detail may be made therein without departing from the spirit and scope of the present disclosure.

1. A semiconductor device, comprising:
a substrate;
semiconductor patterns that are stacked on the substrate, extend in a first direction parallel to a top surface of the substrate, and are spaced apart from each other;
a gate electrode comprising horizontal portions, that extend in a second direction crossing the first direction, and a vertical portion, that is in contact with the horizontal portions and extends in a third direction perpendicular to the top surface of the substrate;
a gate insulating layer between the semiconductor patterns and the gate electrode; and
a ferroelectric layer between the gate insulating layer and the gate electrode,
wherein each of the semiconductor patterns comprises impurity regions and a channel region between the impurity regions,
the vertical portion is on a first side surface of the channel region, and
the horizontal portions are on a top surface and a bottom surface of the channel region.

2. The semiconductor device of claim 1, wherein the gate insulating layer is in contact with the first side surface, the top surface, and the bottom surface of the channel region.

3. The semiconductor device of claim 1, wherein the channel region has a first length in the second direction,
wherein a portion of the channel region, which is overlapped with the horizontal portions, has a second length in the second direction, when viewed in a plan view, and
wherein the second length is larger than half of the first length.

4. The semiconductor device of claim 1, wherein the horizontal portions are spaced apart from each other in the third direction.

5. The semiconductor device of claim 1, further comprising an insulating pattern that is on a second side surface of the channel region that is opposite to the first side surface.

6. The semiconductor device of claim 5, wherein a portion of the gate insulating layer is in contact with the insulating pattern.

7. The semiconductor device of claim 1, wherein a thickness of the ferroelectric layer adjacent to the vertical portion is equal to a thickness of the ferroelectric layer adjacent to the horizontal portions.

8. The semiconductor device of claim 1, wherein a thickness of the vertical portion in the second direction is different from a thickness of the horizontal portions in the third direction.

9. The semiconductor device of claim 1, wherein the semiconductor device further comprises a metal pattern between the gate insulating layer and the ferroelectric layer.

10. The semiconductor device of claim 1, further comprising a filling pattern between two of the semiconductor patterns that are adjacent to each other in the third direction,
wherein the filling pattern is spaced apart from the ferroelectric layer and is enclosed by the vertical portion and the horizontal portions of the gate electrode.

11. The semiconductor device of claim 1, further comprising a data storing pattern connected to one of the impurity regions,
wherein the data storing pattern comprises a bottom electrode, a top electrode, and a capacitor insulating layer between the bottom electrode and the top electrode.

12. The semiconductor device of claim 11, wherein the capacitor insulating layer of the data storing pattern comprises a ferroelectric material.

13. The semiconductor device of claim 1, further comprising an interlayer insulating pattern between two of the impurity regions of the semiconductor patterns that are adjacent to each other in the third direction.

14. A semiconductor device, comprising:
a substrate;
semiconductor patterns that are on the substrate and spaced apart from each other in a vertical direction, the semiconductor patterns comprising a first side surface and a second side surface that are opposite to each other;
an outer gate electrode comprising a vertical portion, that is on the first side surface, and a horizontal portion, that protrudes from the vertical portion;
an inner gate electrode on the second side surface of the semiconductor patterns;
an outer ferroelectric layer between the outer gate electrode and the semiconductor patterns; and
an inner ferroelectric layer between the inner gate electrode and the semiconductor patterns,
wherein the horizontal portion extends between two of the semiconductor patterns that are adjacent to each other in the vertical direction.

15. The semiconductor device of claim 14, wherein the horizontal portion is on a top surface and a bottom surface of the two of the semiconductor patterns.

16. The semiconductor device of claim 14, wherein each of the semiconductor patterns further comprises impurity regions and a channel region between the impurity regions, and
wherein the channel region is between the vertical portion and the inner gate electrode.

17. The semiconductor device of claim 14, wherein the vertical portion extends in the vertical direction, and
the inner gate electrode is parallel to the vertical portion.

18. A semiconductor device, comprising:
a substrate;
an insulating layer on the substrate;
first semiconductor patterns that are on the insulating layer, extend in a first direction parallel to a top surface of the substrate, and are spaced apart from each other in a vertical direction;
second semiconductor patterns that are on the insulating layer, extend in the first direction, and are spaced apart from each other in the vertical direction;
an insulating pattern between the first semiconductor patterns and the second semiconductor patterns;
a bit line extending in a second direction crossing the first direction and connected to at least one of the first semiconductor patterns and at least one of the second semiconductor patterns;
a first gate structure on bottom surfaces, top surfaces, and outer side surfaces of the first semiconductor patterns; and
a second gate structure on bottom surfaces, top surfaces, and outer side surfaces of the second semiconductor patterns,
wherein the first semiconductor patterns are spaced apart from the second semiconductor patterns in the second direction, and
wherein the first gate structure and the second gate structure are symmetrical to each other in the second direction.

19. The semiconductor device of claim 18, wherein the first gate structure comprises a first gate electrode and a first ferroelectric layer that is between the first gate electrode and the first semiconductor patterns, and
the second gate structure comprises a second gate electrode and a second ferroelectric layer that is between the second gate electrode and the second semiconductor patterns.

20. The semiconductor device of claim 18, wherein a portion of the first gate structure and a portion of the second gate structure are in contact with the insulating pattern.

21.-25. (canceled)
